(19) United States
(12) Patent Application Publication
(10) Pub. No.: US 2026/0301810 A1
(43) Pub. Date: Oct. 1, 2026

(54) Method for Resistive Random Access Memory Devices

(71) Applicant: Intrinsic Semiconductor Technologies Ltd., Brill (GB)

(72) Inventors: Adnan MEHONIC, Brill (GB); Fernando L AGUIRRE, Brill (GB); Wing L. NG, Brill (GB); Anthony J KENYON, Brill (GB)

(73) Assignee: Intrinsic Semiconductor Technologies Ltd., Brill (GB)

(21) Appl. No.: 19/631,191

(22) Filed: Mar. 27, 2026

(30) Foreign Application Priority Data
Mar. 27, 2025 (GB) 2504516.2

(51) Int. Cl. G11C 13/00

(52) U.S. Cl. CPC G11C 13/0069; G11C 2013/0083

(57) ABSTRACT

A method of electroforming a resistive random access memory device which includes a resistance switching material is described. The electroforming includes a preconditioning step in which a first voltage exceeding a first threshold voltage is applied across the resistive random access memory device whilst limiting a current through the resistive random access memory device to a first current value. The preconditioning step increases the conductance of the resistive random access memory device without forming a filament. The electroforming also includes a filament forming step after the preconditioning step, in which the filament is formed by passing a current which exceeds the first current value through the resistive random access memory device.

### FIELD OF THE INVENTION

The present invention relates to new methods for electroforming resistive random access memory devices. The present invention also relates to resistive random access memory devices electroformed using these methods.

### BACKGROUND

Existing non-volatile memory technologies face scalability challenges, particularly for embedded applications such as embedded Flash. These challenges may be compounded by demands on programming and read speeds, programming endurance and so forth. As the demand grows for memory devices that are faster, smaller, and more energy-efficient, for example for applications in mobile computing and the Internet of Things (IoT), the shortcomings of current memory solutions have become evident. Consequently, there has been a drive to create new types of memory technology that can overcome the technological shortfalls of existing memory devices.

One emerging technology is Resistive Random Access Memory (RRAM), which appears favourable due to a potential combination of cost-effectiveness, simplicity, and efficiency, especially in embedded memory applications. RRAM has potential as an alternative to traditional embedded Flash memory. The principle of RRAM is to transform typically insulating materials, such as metal or semiconducting oxides, into materials capable of resistance switching. This is achieved by applying voltage pulses that reversibly induce multiple conductance states. In the context of digital memory, one conductance state is used to represent the logic state “1” and another conductance state is used to represent the logic state “0”. Without wishing to be bound by theory, the present understanding is that the applied voltage pulses generate one or more conductive filaments within the (otherwise dielectric) resistance switching material. Typically, a single filament is considered to dominate the device behaviour.

The formation of conductive filaments in RRAM devices is influenced by a large number of factors including, but not limited to, defects in the resistance switching oxide material, the generation of oxygen vacancies, and the movement of oxygen ions. In valence change, or intrinsic, RRAM devices, these filaments are understood to be primarily composed of oxygen vacancies. An electroforming process is thought to initiate these filaments, which allows their electronic states to be reversibly changed, in particular to be:
‘reset’ to a high resistance state (HRS) or
‘set’ to a low resistance state (LRS).

This effect is referred to as resistance switching. This process depends on the precise application of specific voltages and currents, and there is a stochastic element which has remained a significant challenge in the prior art to control sufficiently to permit reliable operation across a large enough number of set/reset cycles.

In addition to RRAM devices including the resistance switching oxide layer between a pair of metallic electrodes, devices have been reported which include a second oxide layer for a variety of intended purposes, see:
Basnet, P. et al. “Asymmetric Resistive Switching of Bilayer HfOₓ/AlO_{y} and AlO_{y}/HfOₓ Memristors: The Oxide Layer Characteristics and Performance Optimization for Digital Set and Analog Reset Switching.” ACS Appl. Electron. Mater. 5, 1859-1865 (2023);
Stathopoulos, S. et al. “Multibit memory operation of metal-oxide bi-layer memristors.”, Sci Rep 7, 17532 (2017);
Lee, M.-J. et al. “A fast, high-endurance and scalable non-volatile memory device made from asymmetric Ta₂O₅₋ₓ/TaO₂₋ₓ bilayer structures”, Nature Mater 10, 625-630 (2011);
Falcone, D. F. et al. “Physical modeling and design rules of analog Conductive Metal Oxide-HfO₂ RRAM.”, in 2023 IEEE International Memory Workshop (IMW) 1-4 (2023), doi:10.1109/IMW56887.2023.10145936;
Stecconi, T. et al. “Filamentary TaOₓ/HfO₂ RRAM Devices for Neural Networks Training with Analog In-Memory Computing.”, Advanced Electronic Materials 8, 2200448 (2022),
Sekar, D. C. et al. “Technology and circuit optimization of resistive RAM for low-power, reproducible operation”, in 2014 IEEE International Electron Devices Meeting 28.3.1-28.3.4 (IEEE, San Francisco, CA, USA, 2014), doi: 10.1109/IEDM.2014.7047125,

An important step in the preparation of RRAM devices is the first formation of the filament in the pristine device. This process is referred to as “electroforming”. The electroforming procedure is performed by applying a voltage pulse or ramp, whilst the current limitation is set to match a desired maximal operational reset current (Iᵣₑₛₑₜ) of the RRAM device. However, to date the maximal operational reset current Iᵣₑₛₜ of reported RRAM devices has been larger (even for a factor of around two) than the targeted operational current. Without wishing to be bound by theory, this is believed to indicate a larger than expected filament is formed. The level of reset current Iᵣₑₛₑₜ persists throughout the operational lifetime of a RRAM device.
Wang, T., Shi, Y., Puglisi, F. M., Chen, S., Zhu, K., Zuo, Y., Li, X., Jing, X., Han, T., Guo, B., Bukvisove, K., Kachtik, L., Kolibal, M., Wen, C., & Lanza, M. (2020). “Electroforming in Metal-Oxide Memristive Synapses”. ACS Applied Materials and Interfaces, 12(10), 11806-11814, https://doi.org/10.1021/acsami.9b19362, describes an example of a prior art electroforming procedure.

### SUMMARY

According to a first aspect of the invention there is provided a method including electroforming a resistive random access memory device which includes a resistance switching material. The electroforming includes a preconditioning step in which a first voltage exceeding a first threshold voltage is applied across the resistive random access memory device whilst limiting a current through the resistive random access memory device to a first current value. The preconditioning step increases the conductance of the resistive random access memory device without forming a filament. The electroforming also includes a filament forming step after the preconditioning step, in which the filament is formed by passing a current which exceeds the first current value through the resistive random access memory device.

The presence or absence of the filament may be determined based on the current-voltage characteristic of the resistive random access memory device. When the filament has formed, there is a linear relationship between current and voltage, at least over a range between (and including) −300 mV and 300 mV. If the current-voltage characteristic of the resistive random access memory device exhibits a non-linear relationship over the range between (and including) −300 mV and 300 mV, this indicates the absence of the filament.

The first threshold voltage may be at least 3 V. The first threshold voltage may be:

$${V}_{TH 1} = {V}_{B}^{*} - 3 {σ}_{B}$$

In which V_{TH1} is the first threshold voltage, V*_{B} is the mean breakdown voltage V_{B} for pristine resistive random access memory devices, and σ_{B} is the standard deviation of the breakdown voltages V_{B} for pristine resistive random access memory devices.

For any given pristine resistive random access memory device, the breakdown voltage V_{B} may be determined as follows: a linear voltage ramp may be applied at a rate of 1 V·s⁻¹ until electrical breakdown is observed. Electrical breakdown may be observed from a sudden increase in the gradient of the current-voltage characteristic, for example exceeding 1 mA·V⁻¹. The voltage reached when electrical breakdown is observed is the breakdown voltage V_{B} for that given resistive random access memory device. The measurement may only be made once per pristine resistive random access memory device, and cannot be repeated. Repetition of measurements across a number of notionally identical (i.e. the same structure, deviating only within manufacturing tolerances) pristine resistive random access memory devices allow the calculation of the mean breakdown voltage V*_{B} and the standard deviation σ_{B} for that structure of resistive random access memory device, and hence calculation of the first voltage threshold V_{TH1}.

The mean breakdown voltage V*_{B} may vary considerably compared to tabulated breakdown fields known for a given resistance switching material in bulk.

The first current value may be less than or equal to 0.1*G₀*V*_{B}, wherein G₀ is the physical constant of the conductance quantum, having value G₀=7.748*10⁻⁵ S.

Whether or not the conductance of the resistive random access memory device has been increased by the preconditioning step may be determined by comparing the conductance of the resistive random access memory device for a bias of 300 mV before and after the preconditioning step.

In a case where the resistive random access memory device exhibits a rectifying, or otherwise asymmetric, current-voltage response, whether or not the conductance of the resistive random access memory device has been increased by the preconditioning step may be determined by comparing the conductance of the resistive random access memory device for a forward bias of 300 mV before and after the preconditioning step. Forward bias corresponds to the polarity of applied voltage which results in the larger current through the resistive random access memory device for a given magnitude of applied voltage.

The electroforming may also include one or more development steps carried out between the preconditioning step and the filament forming step. A sequence may start with the preconditioning step, end with the filament forming step and include the one or more development steps. Each given development step of the one or more development steps may include passing a current through the resistive random access memory device which exceeds a current limit applied during the preceding step of the sequence, such that the given development step increases the conductance of the resistive random access memory device without forming the filament.

The current passed through the resistive random access memory device during the given development step may be less than the maximum current or a current limit applied during a subsequent step of the sequence.

A given development step increases the conductance of the resistive random access memory device without forming the filament if the conductance following that given development step is larger than the conductance before that given development step. The comparison may be made as described in relation to the preconditioning step.

In the general case, the sequence of the method of electroforming may include any number N≥2 of steps, including at least the preconditioning step and the filament forming step.

The filament forming step may include ramping up the current passing through the resistive random access memory device.

The current passing through the resistive random access memory device may be ramped starting from the first current value. The current passing through the resistive random access memory device may be continuous between the preconditioning step and the filament forming step (though the gradient of current with time may be discontinuous). The current passing through the resistive random access memory device during the filament forming step may be ramped starting from the first current value according to a staircase function including one or more steps. A staircase function including a single step is a step function. The step of a step function may occur at the initiation of the filament forming step, or after a predetermined delay following initiation of the filament forming step. The current passing through the resistive random access memory device during the filament forming step may be ramped starting from the first current value according to a linear function. The current passing through the resistive random access memory device during the filament forming step may be ramped starting from the first current value according to a non-linear function. The current passing through the resistive random access memory device during the filament forming step may be ramped starting from the first current value according to a continuous or discontinuous function (for example a spline).

Each step may start immediately following the preceding step. In other words, the filament forming step may start immediately (i.e. continuously) following the end of the last development step or the preconditioning step, in dependence on whether one or more development steps are included. Each given development step may start immediately (i.e. continuously) following the end of the preceding development step or the preconditioning step, in dependence on whether one or more development steps are included.

A delay may separate the start of each step from the end of the preceding step. In other words, the filament forming step may start after a delay following the end of the last development step or the preconditioning step, in dependence on whether one or more development steps are included. Each given development step may start after a delay following the end of the preceding development step or the preconditioning step, in dependence on whether one or more development steps are included.

The delays between each pair of steps may all have the same length, however this is not essential.

During each delay, no current may be passed through the resistive random access memory device.

Alternatively, during each delay the polarity of current passing through the resistive random access device may be reversed, though preferably the current magnitude remains less than or equal to the magnitude of the first current value during any reversal. This process of reversing current may or may not be repeated after each of the optional one or more development steps.

The filament forming step may include applying a voltage across the resistive random access memory device whilst limiting the current through the resistive random access memory device to a second current value which is greater than the first current value.

The voltage applied across the resistive random access memory device during the filament forming step may be less than or equal to the first voltage.

When one or more development steps are used, each given development step of the one or more development steps may include applying a voltage across the resistive random access memory device whilst limiting the current through the resistive random access memory device to a corresponding current value which is greater than the first current value and less than the second current value.

The voltage applied across the resistive random access memory device during the given development step may be less than or equal to the first voltage. In general, during each step of the sequence, the voltage applied across the resistive random access memory device during that step may be less than or equal to the voltage applied across the resistive random access memory device during the preceding step. This may reduce voltage stress on other electronic components connected in series with the resistive random access memory device. For example, a series connected transistor used to limit the current through the resistive random access memory device.

The first current value may be between 10 nA and 10 μA. The first current value may be less than or equal to 5 μA. The first current value may be less than or equal to 4 μA. The first current value may be less than or equal to 3 μA. The first current value may be less than or equal to 2 μA. The first current value may be less than or equal to 1 μA. The first current value may be less than or equal to 500 nA. The first current value may be less than or equal to 200 nA. The first current value may be less than or equal to 100 nA.

The first current value may be between 100 nA and 10 μA. The first current value may be between 1 μA and 10 μA.

A maximum current during the filament forming step may be greater than or equal to 50 μA and less than or equal to 500 μA. The maximum current during the filament forming step may be equal to the second current value.

When one or more development steps are used, a current limit during each given development step of the one or more development steps may be greater than or equal to 1 μA and less than or equal to 100 μA.

The current limit during each given development step may also be greater than the current limit of the preceding step of the sequence, and less than a current limit of the subsequent step in the sequence.

For resistive random access memory devices having nominally identical structures, the first current value (during the preconditioning step) is less than a smallest current limit during any development step(s) (if any), and the second current value (during the filament forming step) is greater than a largest current limit during any development step(s) (if any).

In one preferred example the first current value may be 1 μA and the current during the filament forming step may be limited to a second current value of 10 μA.

In another preferred example, the first current value may be 1 μA and the current during the filament forming step may be limited to a second current value of 100 μA.

In another preferred example, which includes a single development step, the first current value may be 1±0.1 μA, the maximum current during the development step may be limited to a third current value of 10±1 μA, and the maximum current during the filament forming step may be limited to a second current value of 100±10 μA.

The preconditioning step may have a duration between 1 ns and 100 ms. The preconditioning step may have a duration between 1 μs and 500 μs. The preconditioning step may have a duration between 1 μs and 200 μs. The preconditioning step may have a duration between 10 μs and 100 μs.

The filament forming step may have a duration between 1 ns and 100 ms. The filament forming step may have a duration between 1 μs and 500 μs. The filament forming step may have a duration between 1 μs and 200 μs. The filament forming step may have a duration between 10 μs and 100 μs.

Each of the one or more development steps may have a duration between 1 μs and 1 ms. Each of the one or more development steps may have a duration between 1 μs and 500 μs. Each of the one or more development steps may have a duration between 1 μs and 200 μs. Each of the one or more development steps may have a duration between 10 μs and 100 μs.

In general, the duration of the preconditioning step may be the longest due to the stochastic nature of initiating defect formation in the resistive switching oxide material.

When included, each delay between a pair of steps may have a duration between 10 ns and 1 ms. Each delay between a pair of steps may have a duration between 10 ns and 500 μs. Each delay between a pair of steps may have a duration between 10 ns and 200 μs. Each delay between a pair of steps may have a duration between 10 ns and 100 μs. The durations of delays may be the same after every step, though this is not essential.

The electroforming may also include one or more filament development steps carried out after the filament forming step. A second sequence may start with the filament forming step and may progress through the one or more filament development steps. Each given filament development step of the one or more filament development steps may include passing a current through the resistive random access memory device which exceeds a current limit applied during the preceding step of the second sequence, such that the given filament development step increases the conductance of the filament.

The current passed through the resistive random access memory device during the given filament development step may be less than the maximum current or the current limit applied during a subsequent step of the second sequence.

12. The method of any one of claims 1 to 11, wherein a maximum voltage applied across the resistive random access memory device during the preconditioning step is less than or equal to 6 V.

The first voltage exceeds the first threshold voltage and is less than the maximum voltage.

The maximum voltage applied across the resistive random access memory device during the preconditioning step may be less than or equal to 5 V. The maximum voltage applied across the resistive random access memory device during the preconditioning step may be less than or equal to 4 V. The maximum voltage applied across the resistive random access memory device during the preconditioning step may be less than or equal to 3.6 V. The maximum voltage applied across the resistive random access memory device during the preconditioning step may be less than or equal to 3.3 V. The maximum voltage applied across the resistive random access memory device during the preconditioning step may be less than or equal to 3 V.

The maximum voltage applied across the resistive random access memory device during the filament forming step and the one or more development steps may be the same as during the preconditioning step. Alternatively, during each of the filament forming step and the one or more development steps, the maximum voltage may be successively reduced compared to the preceding step of the sequence.

Maximum voltages may not be attained once currents begin to flow through the resistive random access memory device, for example, when driven using constant current source(s).

A maximum voltage applied across the resistive random access memory device during the preconditioning step may be less than or equal to 18 V.

The maximum voltage applied across the resistive random access memory device during the preconditioning step may be less than or equal to 15 V. The maximum voltage applied across the resistive random access memory device during the preconditioning step may be less than or equal to 10 V. The maximum voltage applied across the resistive random access memory device during the preconditioning step may be less than or equal to 9 V. The maximum voltage applied across the resistive random access memory device during the preconditioning step may be less than or equal to 8 V

Current(s) may be passed through the resistive random access memory device using one or more constant current sources. For example, a single, adjustable constant current source may be connected in series with the resistive random access memory device. Alternatively, one or more constant current sources may be connectable in series with the resistive random access memory device in a multiplexed arrangement.

At least one constant current source of the one or more constant current sources may include, or take the form of, a transistor connected or connectable in series with the resistive random access memory device. The transistor may be a field effect transistor. The current through the resistive random access memory device may be limited to a desired current value by controlling the gate voltage of the field effect transistor within the saturation regime.

Alternatively, the transistor may be a bipolar junction transistor, and the current through the resistive random access memory device may be limited to the respective current value by controlling the transistor base current. In still other alternatives, more complex constant current sources (for example including multiple transistors and further components) may be used.

The method may be applied to a resistive random access memory device including a first electrode, a second electrode, and a resistance switching layer formed from a first oxide, between the first electrode and the second electrode.

The resistive random access memory device may include, stacked between the first electrode and the second electrode, the resistance switching layer formed from a first oxide and a conductive layer, the conductive layer capable of receiving oxygen.

The conductive layer may take the form of any material having a greater oxygen affinity than at least one element of the first oxide which is not oxygen.

The conductive layer may include, or take the form of, a metal layer. Additionally or alternatively, the conductive layer may include, or take the form of, a second oxide layer.

The second oxide layer may be formed from an oxide of the metal forming the metal layer. The second oxide layer may include the same elements as the first oxide with a different stoichiometry. The second oxide layer may include different elements (other than oxygen) to the first oxide. When the second oxide layer and the metal layer are both included, the second oxide layer may be disposed between the resistance switching layer and the metal layer. The second oxide layer may include, or take the form of, an oxide of the metal forming the metal layer.

The resistance switching layer may be formed from one or more of silicon oxide, silicon dioxide, silicon nitride, silicon carbide and silicon oxynitride. The resistance switching layer may consist of a single one of the listed compounds. The resistance switching layer may take the form of a mixture, blend or alloy of two or more of the listed compounds.

The preconditioning step may include, or take the form of, applying one or more first voltage pulses across the resistive random access memory device whilst limiting the current through the resistive random access memory device to the first current value. The filament forming step may include, or take the form of, applying one or more second voltage pulses across the resistive random access memory device whilst limiting the current through the resistive random access memory device to a second current value which is greater than the first current value.

When one of more development steps are used, each of the one of more development steps may include, or take the form of, applying one or more respective voltage pulses whilst limiting the current through the resistive random access memory device to a corresponding current value.

The first, second and any intermediate current values (during a development step) may take values as described hereinbefore.

Each first voltage pulse may take the form of a top-hat function. In other words, each first voltage pulse may take the form of a single half-cycle of a square wave. Alternatively, each first voltage pulse may take the form of a voltage ramp. The voltage ramp may be linear. The voltage ramp may be stepped, for example a staircase function having two or more steps. The voltage ramp may be non-linear such as, for example, logarithmic. Alternatively, each first voltage pulse may take the form of a triangular waveform. The triangular waveform may be symmetric (in time) about a maximum voltage value. The triangular waveform may be asymmetric (in time) about the maximum voltage value.

Each first voltage pulse may have a duration between 1 ns and 100 ms. Each first voltage pulse may have a duration between 1 μs and 500 μs. Each first voltage pulse may have a duration between 1 μs and 200 μs. Each first voltage pulse may have a duration between 10 μs and 100 μs.

Each second voltage pulse may take any form described in relation to the first voltage pulses. Each voltage pulse of a development step of the one or more development steps may take any form described in relation to the first voltage pulses.

The preconditioning step may include the steps of:
a) applying a first voltage pulse;
b) measuring the conductance of the resistive random access memory device;
c) in response to the conductance is less than a preconditioning conductance threshold, returning to step a); and
d) in response to the resistance is greater than or equal to the preconditioning conductance threshold, finishing the preconditioning step.

“Conductance” is electrical conductance. In this way, the success of the preconditioning during the first voltage pulse may be verified by measuring the conductance of the resistive random access memory device. If the preconditioning has succeeded (determined by the conductance being at or above the preconditioning conductance threshold), then the method may move on to the next step of the sequence, if used one or more development steps, and ultimately the filament forming step. However, if the preconditioning has not succeeded in response to the first voltage pulse, the first voltage pulse may be iteratively repeated until the preconditioning has been successful to the necessary degree.

The preconditioning conductance threshold may be determined from calibration experiments using resistive random access memory devices having notionally identical structures (which is to say identical to the limits of practical manufacturing).

Such a “form-and-verify” approach may be repeated after each second voltage pulse of the filament forming step, based on a filament conductance threshold (greater than the preconditioning conductance threshold). Equally, when one or more development steps are used, each voltage pulse of each development step may be followed by confirming that the conductance of the device has increased by a required increment, and repeating that voltage pulse if not.

Any such “form-and-verify” loop may have a maximum number of iterations, for example 10 iterations, 20 iterations and so forth. If the resistive random access memory device has not met the required resistance after the maximum number of iterations, the method may output a message indicating that electroforming of that particular resistive random access memory device has not completed. The message may indicate which step did not attain the corresponding conductance threshold. For example, the message may indicate if the failure to obtain the threshold conductance occurred in the preconditioning step, the filament forming step, or one of the development steps. Sub-threshold conductance after the filament forming step may still be usable with additional control measures for setting, resetting and/or reading.

The method of electroforming may include applying a constant or ramped voltage across the resistive random access memory device whilst limiting the current through the resistive random access memory device to a time-varying current value which increases with time, wherein a rate of increase of the time-varying current value is controlled such that the time-varying current value does not exceed the first current value before the cumulative probability of breakdown for the resistive random access memory device exceeds 0.95.

In other words, the rate of increase of the time-varying current value may be controlled so that, relative to the probability of breakdown, the greatest chance of initial breakdown occurring will correspond to a low current. This corresponds to the preconditioning step. As the time-varying current value continues to increase, the initially formed filament may be strengthened in a controlled fashion until the filament is formed. This may alternatively be viewed as a continuum of development steps connecting the preconditioning step to the filament formation step.

The cumulative probability of breakdown for a given resistive random access memory device and a given constant or ramped voltage profile may be readily measured. For example, the same constant or ramped voltage profile intended may be applied to a number of devices (for example several hundred) whilst the current is not limited or limited to a relatively high value such as 100 μA or more. The time to breakdown may be determined by monitoring the current through each resistive random access memory device, with breakdown corresponding to a transition from low (leakage) current to a higher current as a filament is formed (when the current is not limited or not sufficiently limited to prevent filament formation). In this way, the cumulative probability of breakdown as a function of time may be determined. The time to a cumulative breakdown probability of 0.95 may be calculated by interpolation. Alternatively, a Weibull distribution may be fitted to the time-to-breakdown data, and then used to estimate the time corresponding to a cumulative breakdown probability of 0.95. Following such measurements, the rate of increase of the current value may be calibrated as defined.

The rate of increase of the time-varying current value may be linear or non-linear. The time-varying current value may be capped at a maximum current value.

The preconditioning step may include monitoring the current through the resistive random access memory device, and the method may progress from the preconditioning step to the filament forming step, or the first development step when one or more development steps are used, in response to detecting an increase in the conductance through the resistive random access memory device exceeding a preconditioning conductance threshold.

In other words, the length of the preconditioning step may not be precisely set in advance, and the subsequent step (filament forming or development) may be triggered in response to the success of the preconditioning step in causing the conductance to exceed the preconditioning conductance threshold (defined hereinbefore). In this way, in response to detecting successful preconditioning, the current limit may be increased to generate the filament in a controlled manner.

Analogously to delays described hereinbefore, a delay may optionally be inserted between detecting success of the preconditioning step and starting the second step. During such delay, the voltage applied across the resistive random access memory device may be reduced or removed. Alternatively, during the delay between detecting success of the preconditioning step and starting the second step, the applied voltage and current limit of the preconditioning step may be maintained.

The subsequent step (whether a development step or the filament forming step) may proceed in any way described herein. For example, the subsequent step (whether a development step or the filament forming step) may limit the current through the resistive random access memory to a constant or ramped current value. Progression through the sequence of steps after the preconditioning step (including any development steps and ending with the filament forming step) may be automatic, based on predetermined durations and/or delays. Alternatively, progression between each step of the sequence (including any development steps and ending with the filament forming step) may be similarly triggered based on monitoring the conductance of the resistive random access memory device.

According to a second aspect of the invention, there is provided a memory including a plurality of resistive random access memory devices, each resistive random access memory device electroformed using the method of the first aspect.

The memory of the second aspect may include features corresponding to any features of the method of the first aspect. Definitions applicable to the method of the first aspect (and/or features thereof) may be equally applicable to the memory of the second aspect (and/or features thereof).

According to a third aspect of the invention, there is provided a memory including a number of resistive random access memory devices. Each resistive random access memory device including a resistance switching layer formed from a material which exhibits resistance switching. A mean of a distribution of maximum reset currents from switching the plurality of resistive random access memory devices is less than or equal to 150 μA.

Each resistive random access memory device of the memory may have been electroformed using a method of the first aspect.

The material which exhibits resistance switching may include, or take the form of, one or more of silicon oxide, silicon dioxide, silicon nitride, silicon carbide and silicon oxynitride.

The mean of the distribution of maximum reset currents from switching the plurality of resistive random access memory devices may be less than or equal to 140 μA. The mean of the distribution of maximum reset currents from switching the plurality of resistive random access memory devices may be less than or equal to 130 μA. The mean of the distribution of maximum reset currents from switching the plurality of resistive random access memory devices may be less than or equal to 120 μA. The mean of the distribution of maximum reset currents from switching the plurality of resistive random access memory devices may preferably be less than or equal to 110 μA. The mean of the distribution of maximum reset currents from switching the plurality of resistive random access memory devices may more preferably be less than or equal to 100 μA.

The memory of the third aspect may include features corresponding to any features of the method of the first aspect. Definitions applicable to the method of the first aspect (and/or features thereof) may be equally applicable to the memory of the third aspect (and/or features thereof).

According to a fourth aspect of the invention, there is provided a memory including a number of resistive random access memory devices. A first mean of a first distribution of maximum reset currents from switching the plurality of resistive random access memory devices is less than a second mean of a second distribution of maximum reset currents from switching a second plurality of resistive random access memory devices comprised by a comparative memory. The comparative memory has an identical pristine structure to the memory, and the second plurality of resistive random access memory devices of the comparative memory are each electroformed using a single current compliance step such that a yield of electroformed resistive random access memory devices is 95% or more.

A resistive random access memory device of the comparative memory may be considered to have been electroformed if:
It is capable of repeatable switching between high and low resistance states;
In the low resistance state, there is a linear relationship between current and voltage, at least over a range between (and including) −300 mV and 300 mV; and
There is a resistance contrast of at least two times. Resistance contrast may be the ratio of resistances between the high and low resistance states.

The single current compliance step may include applying a single ramped voltage pulse to a maximum of 10 V, whilst limiting the current through the resistive random access memory device to a value greater than or equal to 50 μA.

A difference between the first mean and the second mean may be greater than or equal to the larger of a first standard deviation of the first distribution and a second standard deviation of the second distribution. A difference between the first mean and the second mean may be greater than or equal to two times the larger of the first standard deviation and the second standard deviation. A difference between the first mean and the second mean may be greater than or equal to three times the larger of the first standard deviation and the second standard deviation.

The mean of the second distribution may be larger than the mean of the first distribution with a significance level of 5% when using the appropriate statistical test (depending on the nature of the distribution: normal, non-normal, etc.). The mean of the second distribution may be larger than the mean of the first distribution with a significance level of 2% when using the appropriate statistical test (depending on the nature of the distribution: normal, non-normal, etc.)). The mean of the second distribution may be larger than the mean of the first distribution with a significance level of 1% when using the appropriate statistical test (depending on the nature of the distribution: normal, non-normal, etc.).

Each resistive random access memory device of the memory may have been electroformed using a method of the first aspect.

The memory of the fourth aspect may include features corresponding to any features of the method of the first aspect. Definitions applicable to the method of the first aspect (and/or features thereof) may be equally applicable to the memory of the fourth aspect (and/or features thereof).

Unless self-evidently incompatible, the following features may be applicable to any or all of the preceding aspects.

The layers of the resistive random access memory device may be deposited in the order (without excluding one or more additional, intermediate layers): first electrode, resistance switching layer, conductive layer, and second electrode.

The first electrode may include two or more layers. One, some or all of the layers of the first electrode may be metallic. The second electrode may include two or more layers. One, some or all of the layers of the second electrode may be metallic.

The resistance switching layer may be disposed (or formed) directly on the first electrode. Alternatively, one or more first intermediate layers may separate the resistance switching layer from the first electrode. At least one first intermediate layer may function to modify a chemical potential difference between the first electrode and the resistance switching layer. At least one first intermediate layer may function as a diffusion-barrier layer between the first electrode and the resistance switching layer. At least one first intermediate layer may function to reduce interfacial straining between the first electrode and the resistance switching layer. At least one first intermediate layer may function to reduce lattice mismatch between the first electrode and the resistance switching layer. At least one first intermediate layer may function as an oxygen scavenging layer.

The conductive layer may be disposed (or formed) directly on the resistance switching layer. Alternatively, one or more second intermediate layers may separate the conductive layer from the resistance switching layer. Second intermediate layers may be provided to fulfil any functions described in relation to the first intermediate layers, except between the conductive layer and the resistance switching layer instead of between the first electrode and the resistance switching layer.

The second electrode may be disposed (or formed) directly on the conductive layer. Alternatively, one or more third intermediate layers may separate the second electrode from the conductive layer. Third intermediate layers may be provided to fulfil any functions described in relation to the first intermediate layers, except between the second electrode and the conductive layer instead of between the first electrode and the resistance switching layer.

Alternatively, the layers of the resistive random access memory device may be deposited in the order (without excluding one or more additional, intermediate layers): second electrode, conductive layer, resistance switching layer, and first electrode.

The conductive layer may be disposed (or formed) directly on the second electrode. Alternatively, one or more third intermediate layers (already described) may separate the conductive layer from the second electrode.

The resistance switching layer may be disposed (or formed) directly on the conductive layer. Alternatively, one or more second intermediate layers (already described) may separate the resistance switching layer from the conductive layer.

The first electrode may be disposed (or formed) directly on the resistance switching layer. Alternatively, one or more first intermediate layers (already described) may separate the first electrode from the resistance switching layer.

The second oxide layer may have a resistivity of less than or equal to 5 mΩ·cm. The second oxide layer may have a resistivity of less than or equal to 4 mΩ·cm. The second oxide layer may have a resistivity of less than or equal to 3 mΩ·cm. The second oxide layer may have a resistivity of less than or equal to 2 mΩ·cm. The second oxide layer may have a resistivity of less than or equal to 1.5 mΩ·cm. The second oxide layer may have a resistivity of less than or equal to 1.0 mΩ·cm. The second oxide layer may have a resistivity of less than or equal to 0.5 mΩ·cm.

The resistivity of the second oxide layer may be measured using a four-point probe measurement. The resistivity of the second oxide layer may be measured using a reference second oxide layer deposited on an insulating substrate under the same conditions and to the same thickness.

The second oxide layer may take the form of a metal oxide layer. The second oxide layer may take the form of a metal oxynitride layer.

The second oxide layer may function as an oxygen scavenging layer.

The second oxide may have 20% or more excess metal compared to a stoichiometric second oxide. The second oxide may have 25% or more excess metal compared to a stoichiometric second oxide. The second oxide may have 30% or more excess metal compared to a stoichiometric second oxide. The specified percentages of excess metal may correspond to feedstock ratios during formation of the second oxide layer. The specified percentages of excess metal may be determined using laser-ablation mass-spectrometry.

The resistance switching oxide layer may include, or be formed of, Silicon oxide. The resistance switching layer may be formed from SiOx. The value of x may be between 0.5 and 2 (inclusive of endpoints). The resistance switching layer may be formed of Silicon dioxide.

The second oxide layer may include, or be formed of, one or more of tantalum oxide, hafnium oxide, molybdenum oxide, aluminium oxide, tungsten oxide, gallium oxide, silicon oxide and germanium oxide. The second oxide layer may be formed of tantalum oxide. The second oxide layer may be formed of a single compound. The second oxide may be formed of a mixture, blend or alloy of two or more compounds.

The second oxide layer may include, or be formed from, an oxynitride corresponding to one, some or all of the specifically listed conductive metal oxides.

The resistance switching layer may be formed of silicon oxide, SiOₓ, and the conductive layer may be formed of tantalum oxide. The resistance switching layer may be formed of silicon oxide, SiOₓ, and the conductive layer may be formed of hafnium oxide. The resistance switching layer may be formed of silicon oxide, SiOₓ, and the conductive layer may be formed of molybdenum oxide. The resistance switching layer may be formed of silicon oxide, SiOₓ, and the conductive layer may be formed of aluminium oxide. The resistance switching layer may be formed of silicon oxide, SiOₓ, and the conductive layer may be formed of tungsten oxide. The resistance switching layer may be formed of silicon oxide, SiOₓ, and the conductive layer may be formed of gallium oxide. The resistance switching layer may be formed of silicon oxide, SiOₓ, and the conductive layer may be formed of silicon oxide. The resistance switching layer may be formed of silicon oxide, SiOₓ, and the conductive layer may be formed of germanium oxide.

The resistance switching layer may be formed of silicon dioxide, and the conductive layer may be formed of tantalum oxide. The resistance switching layer may be formed of silicon dioxide, and the conductive layer may be formed of hafnium oxide. The resistance switching layer may be formed of silicon dioxide, and the conductive layer may be formed of molybdenum oxide. The resistance switching layer may be formed of silicon dioxide, and the conductive layer may be formed of aluminium oxide. The resistance switching layer may be formed of silicon dioxide, and the conductive layer may be formed of tungsten oxide. The resistance switching layer may be formed of silicon dioxide, and the conductive layer may be formed of gallium oxide. The resistance switching layer may be formed of silicon dioxide, and the conductive layer may be formed of silicon oxide. The resistance switching layer may be formed of silicon dioxide, and the conductive layer may be formed of germanium oxide.

The resistance switching layer may be formed of silicon nitride, and the conductive layer may be formed of tantalum oxide. The resistance switching layer may be formed of silicon nitride, and the conductive layer may be formed of hafnium oxide. The resistance switching layer may be formed of silicon nitride, and the conductive layer may be formed of molybdenum oxide. The resistance switching layer may be formed of silicon nitride, and the conductive oxide layer may be formed of aluminium oxide. The resistance switching layer may be formed of silicon nitride, and the conductive layer may be formed of tungsten oxide. The resistance switching layer may be formed of silicon nitride, and the conductive layer may be formed of gallium oxide. The resistance switching layer may be formed of silicon nitride, and the conductive layer may be formed of silicon oxide. The resistance switching layer may be formed of silicon nitride, and the conductive layer may be formed of germanium oxide.

The resistance switching layer may be formed of silicon carbide, and the conductive layer may be formed of tantalum oxide. The resistance switching layer may be formed of silicon carbide, and the conductive layer may be formed of hafnium oxide. The resistance switching layer may be formed of silicon carbide, and the conductive layer may be formed of molybdenum oxide. The resistance switching layer may be formed of silicon carbide, and the conductive layer may be formed of aluminium oxide. The resistance switching layer may be formed of silicon carbide, and the conductive layer may be formed of tungsten oxide. The resistance switching layer may be formed of silicon carbide, and the conductive layer may be formed of gallium oxide. The resistance switching layer may be formed of silicon carbide, and the conductive layer may be formed of silicon oxide. The resistance switching layer may be formed of silicon carbide, and the conductive layer may be formed of germanium oxide.

The resistance switching layer may be formed of silicon oxynitride, and the conductive layer may be formed of tantalum oxide. The resistance switching layer may be formed of silicon oxynitride, and the conductive layer may be formed of hafnium oxide. The resistance switching layer may be formed of silicon oxynitride, and the conductive layer may be formed of molybdenum oxide. The resistance switching layer may be formed of silicon oxynitride, and the conductive layer may be formed of aluminium oxide. The resistance switching layer may be formed of silicon oxynitride, and the conductive layer may be formed of tungsten oxide. The resistance switching layer may be formed of silicon oxynitride, and the conductive layer may be formed of gallium oxide. The resistance switching layer may be formed of silicon oxynitride, and the conductive layer may be formed of silicon oxide. The resistance switching layer may be formed of silicon oxynitride, and the conductive layer may be formed of germanium oxide.

The resistance switching layer may be amorphous. Alternatively, the resistance switching layer may be crystalline or polycrystalline.

The conductive layer may be amorphous. Alternatively, the conductive layer may be crystalline or polycrystalline.

The resistance switching layer may have a thickness of between 0.5 nm and 20 nm. The thickness range for the resistance switching layer may be inclusive of endpoints. The thickness of the resistance switching layer may be between 1 nm and 10 nm. The thickness of the resistance switching layer may be between 2 and 4 nm.

The conductive layer may have a thickness of between 1 nm and 40 nm. The thickness range for the conductive layer may be inclusive of endpoints. The thickness of the conductive layer may be between 2 nm and 20 nm. The thickness of the conductive oxide may be between 3 nm and 10 nm.

An oxygen affinity of the conductive layer may be greater than or equal to 2 times an oxygen affinity of the resistance switching layer. The oxygen affinity of the conductive layer may be greater than or equal to 3 times an oxygen affinity of the resistance switching layer. The oxygen affinity of the conductive layer may be greater than or equal to 4 times an oxygen affinity of the resistance switching layer. The oxygen affinity of the conductive layer may be greater than or equal to 5 times an oxygen affinity of the resistance switching layer. The oxygen affinity of the conductive layer may be greater than or equal to 10 times an oxygen affinity of the resistance switching layer. The oxygen affinity of the conductive layer may be greater than or equal to 15 times an oxygen affinity of the resistance switching layer. The oxygen affinity of the conductive layer may be greater than or equal to 20 times an oxygen affinity of the resistance switching layer.

### BRIEF DESCRIPTION OF THE DRAWINGS

Certain embodiments of the present invention will now be described, by way of example, with reference to the accompanying drawings in which:

FIG. 1 is a schematic cross section of a first example of a RRAM device;

FIG. 2 is a schematic cross section of a second example of a RRAM device;

FIG. 3 is a schematic cross section of a third example of a RRAM device;

FIG. 4 schematically illustrates a portion of a circuit for operating a RRAM device;

FIG. 5 is a current-voltage characteristic for a switching cycle of a RRAM device, including annotations of several parameters;

FIG. 6A is a process flow diagram of a prior art electroforming process;

FIG. 6B schematically illustrates electrical signals of an example of the prior art electroforming process shown in FIG. 6A;

FIGS. 6C and 6D schematically illustrate electroformed RRAM devices of differing active areas;

FIG. 7A is a process flow diagram of a multi-step electroforming process;

FIG. 7B schematically illustrates electrical signals of an example of the multi-step electroforming process shown in FIG. 7A;

FIG. 8 schematically illustrates reducing an applied voltage during successive steps of a multi-step electroforming process;

FIG. 9 illustrates ramped voltage pulses;

FIG. 10 illustrates triangular voltage pulses;

FIG. 11 presents, for the first example of a RRAM device shown in FIG. 1, a comparison of maximum reset currents resulting from a prior art electroforming process and three examples of multi-step electroforming processes;

FIG. 12 presents, for the second example of a RRAM device shown in FIG. 2, a comparison of maximum reset currents resulting from a prior art electroforming process and three examples of multi-step electroforming processes;

FIG. 13 presents a histogram corresponding to one of the data series plotted in FIG. 11;

FIG. 14 compares maximum reset currents across a number of switching cycles between a prior art electroforming process and a multi-step electroforming process; and

FIG. 15 schematically illustrates electrical parameters of an example of a second multi-step electroforming process.

### DETAILED DESCRIPTION OF CERTAIN EMBODIMENTS

In the following description, like elements are denoted by like reference numerals.

Precise control of resistance switching requires careful consideration of the electrical, chemical, and thermal properties of the layers comprising a RRAM device. The present invention is based, at least in part, on the inventors' insight that changes in the method used for the initial electroforming of RRAM devices may provide improved control over the size of the filament formed. The present specification describes improved electroforming methods controlled into at least two steps—a preconditioning step and a filament forming step, during which currents are controlled at different levels. Optionally, one or more intermediate development steps may be included before the filament forming step, and/or one or more filament development steps may be carried out after the filament forming step.

Electroforming methods described in the present specification may reduce the values of reset currents Iᵣₑₛₑₜ needed during switching for the operational lifetime of the device. Additionally, the variability between RRAM devices within an array (such as a memory) may be reduced by improved control over the electroforming process.

The electroforming methods described in the present specification may be of particular interest when the resistance switching layer of an RRAM device is formed from one or more of silicon oxide, silicon dioxide, silicon nitride, silicon carbide and silicon oxynitride, or a mixture, blend or alloy of two or more of the preceding compounds. Such materials systems have advantages in terms of costs and compatibility with CMOS processing nodes, but have previously been harder to produce and electroform for resistance switching applications.

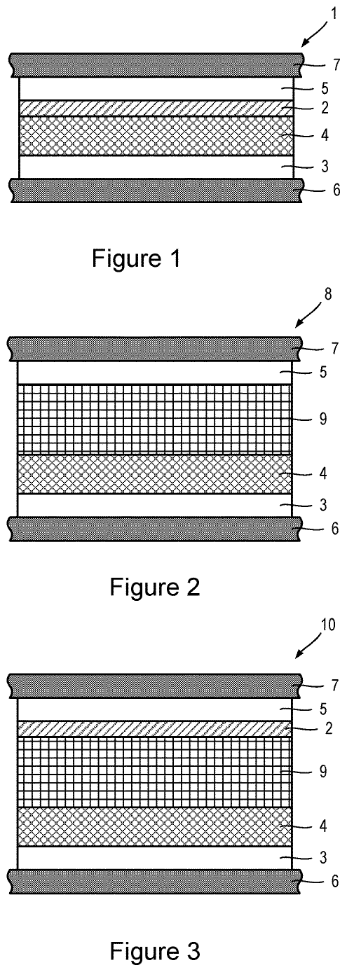

Understanding of the improved electroforming methods of the present specification may benefit from a brief discuss of the structure and operation of RRAM devices. Referring to FIG. 1, a schematic cross-section of a first example of a RRAM device 1 is shown (hereinafter the “first” RRAM device 1).

The first RRAM device 1 includes a metal scavenging layer 2. The first RRAM device 1 is an example of a type of metal-insulator-metal (MIM) stack. The first RRAM device 1 includes, in order, a first metallic electrode 3, a resistance switching layer 4, the metal scavenging layer 2, and a second metallic electrode 5. The relative thicknesses of layers are not shown to scale in FIG. 1. The function of the metal scavenging layer 2 is to facilitate ion exchange with the resistance switching layer 4 to facilitate switching. However, the functions of metal scavenging layer 2 are not critical to the present electroforming methods, and are consequently not discussed in detail herein.

The materials of the first 3 and second 5 electrodes are selected for use with the material of the resistance switching layer 4 on the basis of a variety of factors including (but not limited to) chemical compatibility, work function and so forth. One example of a material useable for the first 3 and second 5 electrodes is titanium nitride TiN. Either or both of the first electrode 3 and the second electrode 5 may be formed as multilayer structures. The first RRAM device 1 stack may also incorporate additional layers (not shown) disposed between any of the illustrated layers to perform functions including, but not limited to, adjustment of the local stoichiometry, adjustment of the density of oxygen vacancies, improving interface matching and so forth.

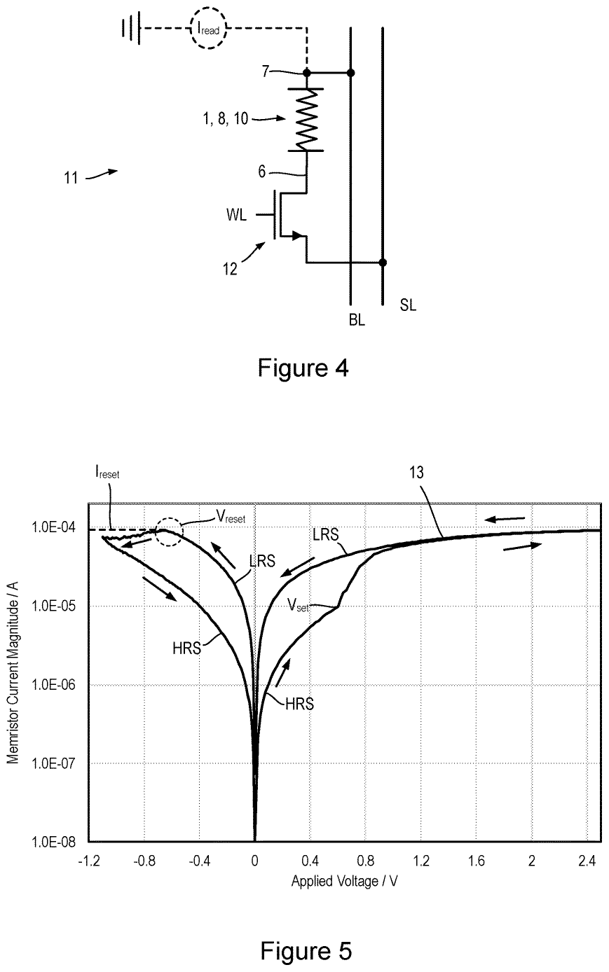

The first RRAM device 1 can be used to switch between two resistance states, representing logic ‘1’ or logic ‘0’, to represent a single bit of data. Typically, a large number of first RRAM devices 1 are arranged and interconnected in an array to form a memory. This is represented in FIG. 1 by the connection of the first electrode 3 to a first metallised layer/trace 6 and the connection of the second electrode 5 to a second metallised layer/trace 7. The configuration of a RRAM device such as the first RRAM device 1 into a memory array configured using conventional 1-Transistor-1-Resistor (1T1R) memory cell is described hereinafter in relation to FIG. 4.

The first RRAM device 1 illustrated in FIG. 1 may be implemented using a range of different materials for each layer, including using silicon-based materials for the resistance switching layer 4. The first electrode 3 typically has a thickness in the range between 10 nm and 100 nm (inclusive of end points), for example 60 nm. Similarly, the second electrode 3 typically has a thickness in the range between 10 and 100 nm (inclusive of end points), for example 60 nm. Examples of materials used for the electrodes 3, 4 include, without being limited to, titanium nitride TiN, titanium Ti, tungsten W, gold Au, molybdenum Mo, nickel Ni and so forth. Either or both of the first 3 and second 5 electrodes may take the form of a multilayer-electrode. For example, the first electrode 3 be formed as a stack of two or more layers and/or the second electrode 5 be formed as a stack of two or more layers

The resistance switching layer 4 typically has a thickness in the range between 1 nm and 50 nm (inclusive of endpoints), more preferably between 1 nm and 15 nm (inclusive of endpoints), for example 3 nm. Examples of materials which can be used for the resistance switching layer 4 of the first RRAM device 1 include silicon oxide SiOₓ (0.5≤x≤2) or other suitable silicon-based dielectrics for memory resistors, such as silicon nitride, silicon carbide, or silicon oxynitride. However, non-silicon-based materials like oxides of hafnium, tantalum, titanium, zinc, aluminium, niobium, among others, may also be utilized. Typically, the resistance switching layer 4 may be amorphous, however crystalline/poly-crystalline materials may be used in some examples.

The metallic scavenging layer 2 typically has a thickness in the range between 1 nm and 30 nm (inclusive of endpoints), for example 10 nm. Examples of materials which can be used for the metallic scavenging layer include titanium Ti, Molybdenum Mo, Hafnium Hf, tantalum Ta, tungsten W, and so forth.

The first RRAM device 1 is described herein to provide context and understanding of RRAM devices in general, and of specific experimentally characterised examples described hereinafter. However, the precise structure of the layers above and below the resistance switching layer 4 are not critical to the operation of the electroforming methods described herein. The present methods rely on the control of currents through the RRAM device 1 stack during each step of the electroforming process, as described hereinafter. Any other structures of RRAM device may equally by electroformed using the present methods.

For example, referring also to FIG. 2, a schematic cross-section of a second example of a RRAM device 8 is shown (hereinafter the “second” RRAM device 8).

The second RRAM device 8 includes the first metallic electrode 3 and the second metallic electrode 5. A resistance switching layer 4 and a conductive oxide layer 9 are stacked between the first 3 and second 5 electrodes. In the example shown in FIG. 2, the resistance switching layer 4 is disposed between the first electrode 3 and the conductive oxide layer 9. However, the second RRAM device 8 may instead have the resistance switching layer 4 disposed between the second electrode 5 and the conductive oxide layer 9.

The second RRAM device 8 differs from the first RRAM device 1 in that the metallic scavenging layer 2 is replaced with the conductive oxide layer 9. The conductive oxide layer may perform a role in ionic exchange, amongst other functions.

The first 3 and second 5 electrodes, and the resistance switching layer 4, may be formed using any materials described in relation to the first RRAM device 1, and may be formed to thicknesses within the same ranges.

A large range of conductive oxides may be used, including but not limited to metal oxides, and semiconductor oxides. For example, the conductive oxide layer 9 may be formed from one or more of tantalum oxide, hafnium oxide, molybdenum oxide, aluminium oxide, tungsten oxide, gallium oxide, silicon oxide and germanium oxide. Additionally or alternatively, the conductive oxide layer 9 may include oxynitrides, for example of the metals/semiconductors mentioned hereinbefore. The conductive oxide layer may consist of a single material, or may take the form of a mixture, blend or alloy of two or more materials.

The conductive oxide layer 10 has a thickness typically in the range between 1 nm and 40 nm (inclusive of endpoints). The thickness may be varied depending on the materials used, for example using tantalum oxide a thickness in the range of 5 nm to 30 nm has been found to be useful. Typically, the conductive oxide layer 9 may have an amorphous structure, though the second RRAM device 8 could alternatively use a crystalline or polycrystalline conductive oxide layer 9.

The second RRAM device 8 stack may also incorporate additional layers (not shown) disposed between any of the illustrated layers to perform functions including, but not limited to, adjustment of the local stoichiometry, adjustment of the density of oxygen vacancies, improving interface matching (e.g. reducing interfacial straining and/or lattice mismatches), modifying a chemical potential difference, providing a diffusion barrier, reducing interfacial straining and so forth.

For example, referring also to FIG. 3, a schematic cross-section of a third example of a RRAM device 10 is shown (hereinafter the “third” RRAM device 10).

The third RRAM device 10 includes the resistance switching layer 4, the conductive oxide layer 9 and the metallic layer 2 stacked in order between the first metallic electrode 3 and the second metallic electrode 5. The materials and thicknesses of each layer may be as described in relation to the first RRAM device 1 and/or the second RRAM device 8.

In the third RRAM device, the conductive oxide layer 9 may take the form of the oxide of a metal used for the metallic layer 2. Alternatively, the conductive oxide layer 9 may be of a different metal to the overlying metallic layer 2.

The electroforming methods of the present specification are applicable to any of the illustrated first 1, second 8 and third 10 RRAM devices, but are not limited to these structures. For example, in other types of RRAM device, the conductive oxide layer 9 may be replaced by other conductive compounds such as nitrides, oxynitrides and so forth.

### Operation of Resistive Random Access Memory Devices

Referring also to FIG. 4, a portion of a circuit 11 for reading and writing data to an RRAM device 1, 8, 10 is shown.

The circuit 11 includes one transistor 12 connected in series with an RRAM device such as the first 1, second 8 or third 10 RRAM device. The circuit 11 is a single cell of a large number grouped into an array. The configuration is sometimes referred to as “1T1R”.

The first metallised layer 6 is connected to a source line SL and the second metallised layer 7 is connected via the transistor 12 (sometimes termed an “addressing” or “access” transistor) to a bit line BL. The gate of the transistor 12 is connected to a word line WL.

In a memory, a large number of RRAM devices 1, 8, 10 are arranged in an array, which each connected between a different pairing of a bit line BL and a source line SL.

Individual RRAM devices 1, 8, 10 may be addressed for reading and/or writing using the corresponding combination of bit line BL, source line SL and word line WL.

In order to set the RRAM device 1, 8, 10 to a low-resistance state (LRS), the transistor 12 is set open using the word line WL, and a set voltage pulse VPₛₑₜ is applied between the bit line BL and source line SL.

In order to reset the RRAM device 1, 8, 10 to a high-resistance state (HRS), the transistor 12 is set open using the word line WL, and a reset voltage pulse VPᵣₑₛₑₜ is applied between the bit line BL and source line SL.

The polarity or the set voltage pulse VPₛₑₜ will depend on the specific RRAM device used 1, 8, 10, but the reset voltage pulse VPᵣₑₛₑₜ will be of the opposite polarity to the set voltage pulse VPₛₑₜ.

In order to read the resistance state (LRS or HRS) of the RRAM device 1, 8, 10, the resistance of the RRAM device 1, 8, 10 is measured. This can be done in different ways, for example, the transistor 12 may be set open using the word line WL, and a known voltage Vread applied between the bit line BL and source line SL. The resistance state of the RRAM device 1, 8, 10 can be determined by monitoring the resulting current Iread.

Alternatively, a constant current source (for example a second transistor) may drive a read current Iread through the RRAM device 1, 8, 10 to a grounded source line SL, and the bit line BL may be used to readout the voltage Vread developed across the RRAM device 1, 8, 10 which will reflect the resistance state Switching of RRAM devices 1, 8, 10 has a stochastic element. The magnitudes of voltage pulses VPₛₑₜ/VPᵣₑₛₑₜ are calibrated for a specific structure of RRAM device 1, 8, 10 to maximise the probability of triggering the desired switching in a single pulse. In practice, the desired resistance state may be set using a write-and-verify process in which the state is read to confirm switching was successful. If necessary, the voltage pulse VPₛₑₜ/VPᵣₑₛₑₜ is repeated until the switching is confirmed or a maximum number of attempts is reached. The values for readout Vread, Iread are calibrated to ensure that the probability of triggering a set or reset is negligible.

Referring also to FIG. 5, a median current-voltage (I-V) characteristic 13 is shown for an example of the second RRAM device 8.

For completeness, the experimental data shown in FIG. 5 were obtained as median current-voltage characteristics obtained by testing 50 second RRAM devices 8. Testing of each second RRAM device 1 was repeated 5 times. Each second RRAM device 8 was produced with:
a 60 nm thick first electrode 3 formed of titanium nitride TiN;
a 3 nm thick resistance switching layer 4 formed of silicon oxide SiOₓ;
a 30 nm thick conductive oxide layer 9 formed of Tantalum oxide TaOₓ having a resistivity of less than 1 mΩ·cm; and
a 60 nm thick first electrode 3 formed of titanium nitride TiN.

The I-V data were obtained using a sweep rate of ~0.1 V·s⁻¹. Arrows shown in FIG. 5 indicate the sweep direction relative to the plotted data. The RRAM device 8 under test was connected in series with the drain of a field-effect transistor (FET). The gate voltage of the FET was controlled to limit the currents passing through the RRAM device 8. External limitation of currents was used because the specific second RRAM devices 8 used did not exhibit self-limitation of the current in the low-resistance state LRS.

The I-V characteristic 13 is reproduced here purely for the purpose of illustrating several key parameters relating to switching of an RRAM device. Although this data corresponds to a specific example of the second RRAM device 8, the parameters illustrated are common to I-V characteristics of any type of resistance switching RRAM device.

The set voltage threshold Vₛₑₜ corresponds to the voltage at which the gradient of the current-voltage I-V characteristic 13 sharply rises. The set voltage threshold Vₛₑₜ has a stochastic element, and is a function of, amongst other factors the materials, the structure and the history of an RRAM device 1, 8, 10. In general, the set voltage threshold Vₛₑₜ will vary both between nominally identical (to within fabrication tolerances) RRAM devices 1, 8, 10, and also between different switching cycles of setting and resetting for each individual RRAM device 1, 8. Consequently, discussions herein of the set voltage threshold Vₛₑₜ shall refer to statistical measures thereof. The magnitude VPₛₑₜ of set pulses needs to be calibrated for the specific structure and materials of a specific RRAM device 1, 8, 10, to ensure a high probability of switching. Consequently, reduction in the distribution width of the set voltage thresholds Vₛₑₜ both for repeated set/reset cycles of a single RRAM device 1, 8, 10 and amongst an ensemble of many RRAM devices 1, 8, 10 is desirable, as the reliability of calibrating a set pulse VPₛₑₜ may be improved.

The set voltage threshold Vₛₑₜ may be measured by applying voltage sweeps across a RRAM device 1, 8, 10 to an amplitude Vₘₐₓ, and measuring the resulting current to obtain I-V characteristics as presented in FIG. 5. If the applied voltage equals or exceeds the set voltage threshold Vₛₑₜ, then forward (from 0 V to |Vₘₐₓ|) and backward (|Vₘₐₓ| to 0 V) sweeps will exhibit a permanent current-voltage hysteresis (as shown in FIG. 5). Conversely, if the voltage sweep remains below the set voltage threshold, i.e.

|Vₘₐₓ|<Vₛₑₜ, then the forward and backward sweeps will not demonstrate hysteresis in the current-voltage curve. In other words, when the voltage is ramped back down to 0 V, the current will follow the same path on the I-V plot as it did when the voltage was ramped up to |Vₘₐₓ|. The sign of the sweep upper bound Vₘₐₓ may be positive or negative depending on the polarity for the set operation.

In this way, the set voltage threshold Vₛₑₜ can be determined by performing multiple sweeps and iteratively increasing the sweep upper bound |Vₘₐₓ| until I-V hysteresis is observed. The corresponding sweep upper bound |Vₘₐₓ| for which I-V hysteresis is first observed corresponds to the set voltage threshold Vₛₑₜ. The sweeps should be conducted at a voltage ramp rate corresponding to a control circuit (not shown) intended to control the RRAM device 1, 8 10 in use, because the set voltage threshold Vₛₑₜ does also exhibit a ramp rate dependence due to the stochastic nature of the process.

The reset threshold voltage Vreset is characterised as the voltage at which the resistance of a RRAM device 1, 8, 10 starts to increase. On the I-V characteristic 13, this manifests as a point where the current I stops increasing with increasing amplitude of applied voltage V, and instead starts to decrease. This point also represents the maximum reset current, denoted herein Iᵣₑₛₑₜ. The magnitude and variability of the maximum reset current Iᵣₑₛₑₜ is shown herein to be correlated to the conditions of electroforming. The electroforming methods of the present specification may provide reductions of the maximum reset current Iᵣₑₛₑₜ, reducing power consumption during operation.

The reset voltage threshold Vreset has a stochastic element, and is a function of, amongst other factors the materials, the structure and the history of an RRAM device 1, 8, 10. In general, the reset voltage threshold Vreset will vary both between nominally identical (to within fabrication tolerances) RRAM devices 1, 8, 10, and also between different switching cycles of setting and resetting for each individual RRAM device 1, 8, 10. Consequently, discussions of the reset voltage threshold Vreset herein shall refer to statistical measures thereof. The magnitude VPᵣₑₛₑₜ of reset pulses needs to be calibrated for the specific structure and materials of a specific RRAM device 1, 8, 10, to ensure a high probability of switching. The electroforming methods of the present specification may provide for reductions in the variability of the maximum reset current Iᵣₑₛₑₜ, improving the reliability of calibrating a reset pulse VPᵣₑₛₑₜ magnitude.

The operating magnitudes for switching pulses VPₛₑₜ, VPᵣₑₛₑₜ are not based on median values, since this would only switch 50% of RRAM devices 1, 8, 10 in an array. Instead, the operating magnitudes VPₛₑₜ, VPᵣₑₛₑₜ for set and reset pulses should be set to ensure that the probability of the set/reset pulse exceeding the respective threshold Vₛₑₜ, Vᵣₑₛₜ is as high as possible. Setting the operating magnitudes VPₛₑₜ, VPᵣₑₛₑₜ arbitrarily high is not viable though, since excessive potentials may lead to undesired reset under polarity intended for setting and/or undesired set under polarity intended for resetting.

For example, the magnitudes VPₛₑₜ, VPᵣₑₛₑₜ of set and reset voltage pulses may be set to correspond to voltage values which permit correct switching of all the RRAM devices 1, 8, 10 in an array (following quality control checks for fabrication yield) for at least 10,000 switching cycles with a resistance contrast between high and low resistance states of at least 10 times (i.e. the low resistance state is at least 10 times lower than the high resistance state). Quality control checks for fabrication yield involve identifying and excluding any RRAM device(s) 1, 8, 10 which are not demonstrating the correct initial behaviours following the initial electroforming: for example, any improved RRAM device(s) 8 which do not exhibit set-reset cycling or which have an initial conductance which is too high (e.g. 10 times the mean). One example of switching cycles for calibrating this condition on the magnitudes of set/reset voltage pulses is met may be performed using a write-and-verify approach in which a set operation is applied by:
a) Applying a set voltage pulse VPₛₑₜ to the RRAM device 1, 8, 10 in the high resistance state HRS;
b) Measuring the resistance state of the RRAM device 1, 8, 10. The read potential Vread magnitude is controlled to be less than lower bounds of measured distributions of switching threshold Vₛₑₜ, Vreset;
c) If the resistance state corresponds to the low resistance state LRS, the RRAM device 1, 8, 10 has been set, and a reset operation is then applied to complete the present switching cycle;
d) If the resistance does not correspond to the low resistance state LRS, the preceding steps a) to c) are repeated, up to a threshold number of set pulses VPₛₑₜ, for example between 10 and 20;
e) If the threshold number of pulses is exceeded without obtaining the low-resistance state LRS, the set operation has failed and that RRAM device 1, 8, 10 is no longer usable.

Similarly, a reset operation for determining whether the condition on the magnitudes of set/reset voltage pulses is met may be performed by:
f) Applying a reset voltage pulse VPᵣₑₛₑₜ to the RRAM device 8 in the low resistance state LRS;
g) Measuring the resistance state of the RRAM device 1, 8, 10;
h) If the resistance state corresponds to the high resistance state HRS, the RRAM device 1, 8, 10 has been reset, and the next switching cycle is then started by applying the set operation;
i) If the resistance state does not correspond to the high resistance state HRS, the preceding steps are repeated, up to a threshold number of pulses, for example between 10 and 20. The threshold number of pulses need not be the same for set and reset operations;
j) If the threshold number of pulses is exceeded without obtaining the high-resistance state HRS, the reset operation has failed and the RRAM device 1, 8, 10 is no longer usable.

Whilst this process will require large numbers of switching cycles, and a reasonable number of RRAM devices 1, 8, 10 to be tested, this is not unduly burdensome due to the ease of automating the measurements. Moreover, the need for such calibrations is known and understood within the field of RRAM devices, due to the inherently stochastic nature of such devices. However, whilst stochastic, RRAM devices 1, 8, 10 are used in practice in arrays including vary large numbers of devices with nominally identical (to within manufacturing tolerances) structures and materials, and the statistical distributions of the relevant parameters can then be measured permitting calibrations and also comparisons between different structures, materials and/or histories of arrays of RRAM devices, including the history of the initial electroforming.

### Conventional Electroforming Process

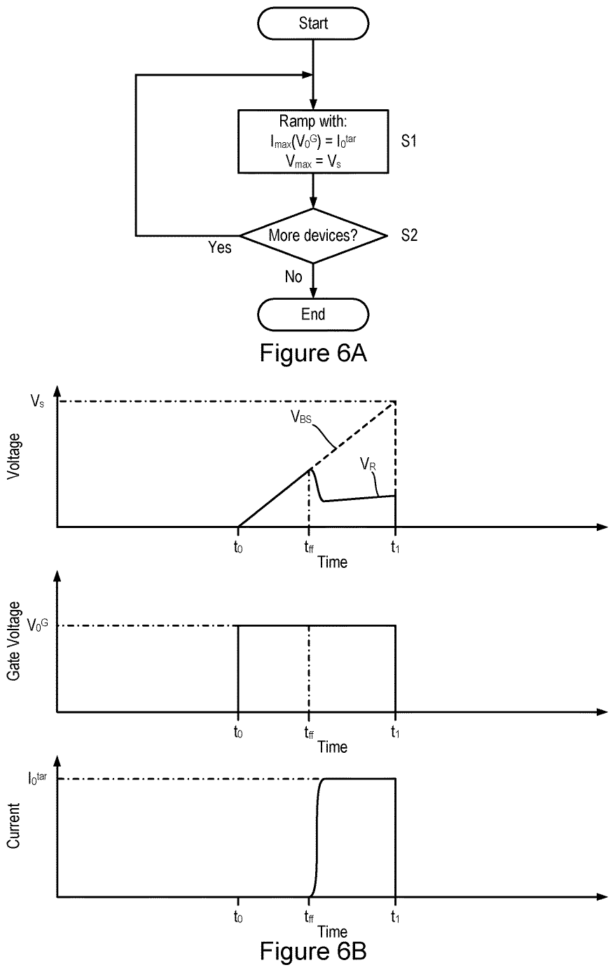

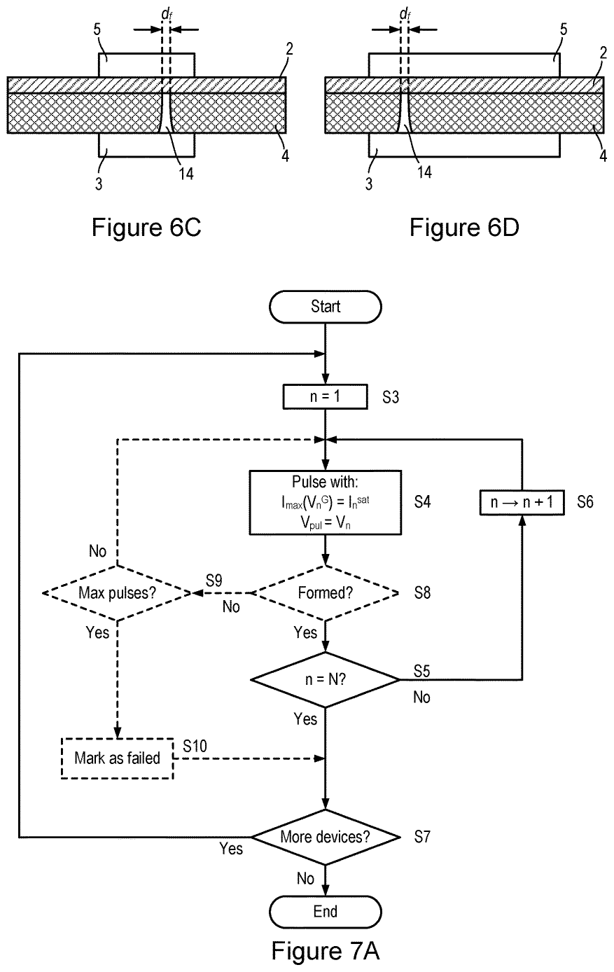

Without wishing to be bound by theory, it is believed that filamentary memristor operation employed in RRAM devices 1, 8, 10 is based on the completion and disruption of a nano sized filament 14 (FIG. 6C) made from conductive defects (for example oxygen vacancies in devices using an oxide based resistance switching layer 4) that electrically connects the metallic electrodes 3, 5.

Prior to write any memory state (1=LRS and 0=HRS or vice-versa) in the RRAM device 1, 8, 10, this filament 14 (FIG. 6C) needs to be created, via a process often referred to as electroforming. The electroforming process involves applying a voltage pulse or ramp across a pristine resistance switching layer 4 until a filament 14 (FIG. 6C) is formed. The voltage required for electroforming is typically larger than that required to fill gap(s) in a disrupted filament 14 (FIG. 6C) during a later set pulse VPₛₑₜ.

Referring also to FIGS. 6A and 6B, a prior art electroforming process is illustrated. FIG. 6A is a process flow diagram of the prior art electroforming process. FIG. 6B schematically illustrates electrical signals of the prior art electroforming process.

The prior art electroforming process shall be described with reference to the circuit 11 shown in FIG. 4, although any suitable control circuitry may be used instead.

A voltage VBs applied between the bit line BL and source line SL is ramped to a maximum value Vₘₐₓ=Vs in a linear ramp with duration Δt=t₁−t₀ (step S1). For the duration of the ramp, the transistor 12 gate is connected via word line WL to a bias voltage V₀^{G} which controls the saturation current Iₘₐₓ to a target value I₀^{tar}.

Initially (t<t_{ff}), the much higher resistance of the RRAM device 1, 8, 10 results in nearly all the voltage VBs being dropped across the RRAM device 1, 8, 10. Eventually, the increasing electric field across the resistance switching layer causes filament formation at time t_{ff}. Once the filament 14 (FIG. 6C) forms, the current I through the RRAM device saturates at the target value I₀^{tar}, and the voltage V_{R} across the RRAM device 1, 8, 10 drops as the resistance becomes comparable to that of the channel resistance of the transistor 12.

If there are further RRAM devices 1, 8, 10 to electroform (step S2|Yes), then the process is repeated for the next 1T1R cell using the corresponding combination of bit line BL, source line SL and word line WL.

Referring also to FIG. 6C, a schematic cross-section of an electroformed first RRAM device 1 is shown.

The precise location within the overlapping area of the first and second metallic electrode 3, 5 where the filament 14 forms is not generally known, though it may be influenced if desired by shaping the boundaries with the metallic electrodes 3, 5 to concentrate the electric field in a particular region. Referring to, for example, Kim et al, “Improved Bipolar Resistive Switching Memory Characteristics in Ge0.5Se0.5 Solid Electrolyte by Using Dispersed Silver Nanocrystals on Bottom Electrode”, Journal of Nanoscience and Nanotechnology, 14(12), 2024, it has been experimentally demonstrated that the sectional area of the filament 14, or equivalently, the filament diameter d_{f}, is proportional to the maximum current I flowing through it during electroforming. Subsequently during use the filament diameter d_{f}, is also proportional to the resistance of the RRAM device 1, 8, 10 in the low resistance state (LRS).

Referring also to FIG. 6D, a schematic cross-section of an electroformed first RRAM device 1 is shown, having larger area of electrodes 3, 5.

Compared to the first RRAM device 1 shown in FIG. 6C, the RRAM device 1 shown in FIG. 6D has a larger overlapping area of the first and second metallic electrodes 3, 5. However, due to the nature of the filament 14, the resistance in the LRS will be substantially the same for the devices shown in FIGS. 6C and 6D. There is of course a lower limit as the device dimensions begins to become comparable with the filament diameter d_{f}, though in practice the filament diameter is much smaller than the thickness of the resistance switching layer 4 (the size is exaggerated in FIGS. 6C and 6D for visual purposes). The filament diameter d_{f} is typically on the scale of several nanometres, and size in the range of 1 to 10 nm have been indirectly estimated based on measured LRS resistances in combination with the structure and materials of device. In any event, the filament resistance is observed to become substantially invariant for overlapping area of the first and second metallic electrodes 3, 5 exceeding about 10 nm by 10 nm. In other words, once the area exceeds the ranges where filament formation may be geometrically constrained, the resistance is dominated by the filament and largely independent of the device area.

Consequently, RRAM devices 1, 8, 10 are suitably characterised by the maximum reset current Iᵣₑₛₑₜ, since this is dominated by the filament 14 and largely independent of the actual overlapping area of the first and second metallic electrodes 3.

After electroforming, during regular switching use, the maximum reset current Iᵣₑₛₑₜ is also determined by the filament diameter d_{f}. The control of the current to I₀^{tar} during the prior art electroforming process is intended to control the filament diameter d_{f}, and in this way to control the resistance of the LRS and the maximum reset current Iᵣₑₛₑₜ. In theory, the maximum reset current Iᵣₑₛₑₜ should be approximately equal to the target current during electroforming I₀^{tar}. However, in practice it has been observed that following the prior art electroforming process leads to maximum reset currents Iᵣₑₛₑₜ which exceed the controlled electroforming current I₀^{tar}, in some cases by as much as a factor of two, indicating larger than expected filaments 14.

### Improved Electroforming Method

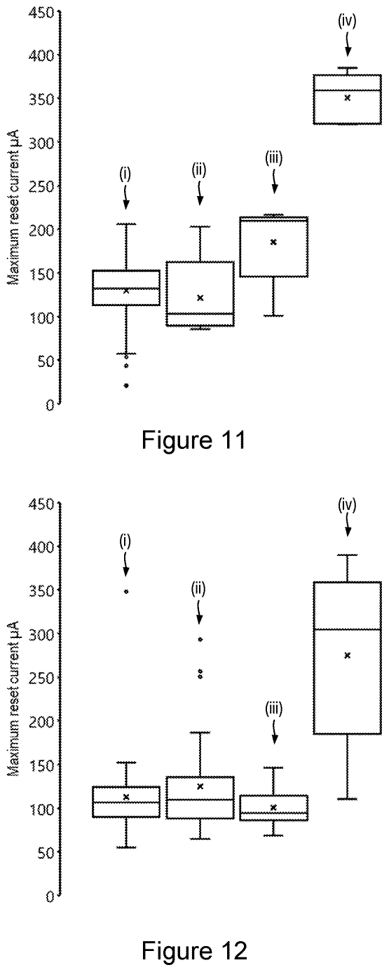

A solution to the problem explained hereinbefore is provided by the multi-step electroforming methods described hereinafter. The filament 14 is formed gradually by applying multiple (more than one) voltage pulses or ramps, each with a current limitation higher than the previous step. This approach allows for a better controllability of the maximal operational current (see also FIGS. 11 to 15).

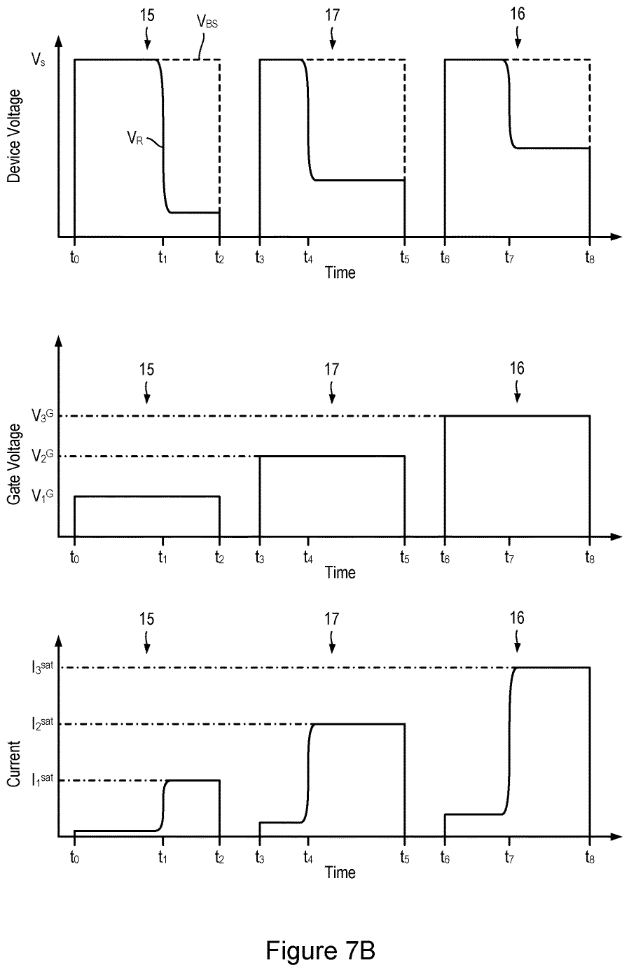

In the simplest form, the improved electroforming method includes two steps: a first, preconditioning step 15 (FIG. 7B), followed by a final, filament forming step 16 (FIG. 7B).

In the preconditioning step 15, a first voltage V₁ exceeding a first threshold voltage V_{TH1} is applied across the RRAM device 1, 8, 10 whilst limiting a current I through the RRAM device 1, 8, 10 to a first current value I₁. For example, using the 1T1R circuit 11, the first voltage V₂ is applied between the bit line BL and source line SL whilst the gate of the transistor 12 is connected via word line WL to a first gate voltage V₁^{G} which corresponds to a saturation current equal to the first current value I₁.

The first current value I₂ is selected so that the preconditioning step 15 increases the conductance of the RRAM device 1, 8, 10, without forming a filament 14. The presence or absence of the filament 14 may be determined directly based on the current-voltage characteristic of the RRAM device 1, 8, 10. When the filament 14 has formed, there will be a linear relationship between current I and voltage V, at least over a range. For example, between (and including) −300 mV and 300 mV. If the I-V characteristic of the RRAM device 1, 8, 10 exhibits a non-linear relationship (for example over the range between (and including) −300 mV and 300 mV), this indicates the absence of the filament 14.

The first current value I₁ may be calibrated by, for example, a series of experiments in which the magnitude of the first current value I₁ is increased, to determine a range in which conductance of the RRAM device 1, 8, 10 increased (by a measurable amount) after the preconditioning step, whilst the I-V characteristics also remained non-linear.

Whether or not the conductance of the RRAM device 1, 8, 10 has been increased by the preconditioning step 15 may be determined by comparing the conductance of the RRAM device 1, 8, 10 for a reference bias (for example 300 mV), before and after the preconditioning step 15.

The first voltage V₂ cannot be arbitrarily low. The processes of defect generation which lead to formation of the filament 14 will not occur unless the electric field across the resistance switching layer 4 is at or close to a threshold field. The process depends to a large extent on factors which are difficult to quantify precisely, such as existing defects in the material of the resistance switching layer 4 and/or roughness in the interfaces leading to electric field concentration. The first threshold voltage V_{TH1} should be no lower than 3 V.

Alternatively, the first threshold value V_{TH1} may be defined relative to calibration measurements of breakdown voltages. For example, the first threshold voltage may be defined as:

$${V}_{TH 1} = {V}_{B}^{*} - 3 {σ}_{B} \qquad ( 1 )$$

In which V_{TH1} is the first threshold voltage, V*_{B} is the mean breakdown voltage V_{B} for pristine (not electroformed) RRAM devices 1, 8, 10, and σ_{B} is the standard deviation of the breakdown voltages V_{B} for pristine RRAM devices 1, 8, 10.

For any given pristine RRAM device 1, 8, 10, the breakdown voltage V_{B} may be determined as follows:
A linear voltage ramp is applied at a rate of 1 V·s⁻¹ until electrical breakdown is observed.
Electrical breakdown may be observed from a sudden increase in the gradient of the current-voltage characteristic, for example exceeding 1 mA·V⁻¹.
The voltage reached when electrical breakdown is observed is the breakdown voltage V_{B} for that given RRAM device 1, 8, 10.

This type of measurement may only be made once per pristine RRAM device 1, 8, 10, and cannot be repeated. Repetition of measurements across a number of notionally identical (i.e. the same structure, deviating by manufacturing tolerances) pristine RRAM device 1, 8, 10 allows the calculation of the mean breakdown voltage V*_{B} and the standard deviation σ_{B} for that structure of RRAM device 1, 8, 10, and hence calculation of the first voltage threshold V_{TH1}. The mean breakdown voltage V*_{B} may vary considerably compared to tabulated breakdown fields known for a given resistance switching material in the bulk.

Once the first threshold voltage V_{TH1} for a given design of RRAM device 1, 8, 10 has been calibrated, a first voltage V₁ and first current value I₁ are selected. For example, the first current value I₁ may be selected to be less than or equal to 0.1×G₀×V*_{B}, with G₀ the physical constant of the conductance quantum, G₀=7.748*10⁻⁵ S. This calculation does not represent an upper bound—suitable values exceeding this may be optimised in some designs. Using this value of the first current value I₁ and the first threshold voltage V_{TH1} as a starting point, the first voltage V₁ may be selected based on calibration experiments, to ensure that the probability of successfully conducting the preconditioning step 15 (determined by checking the conductance before and after) is at least 0.99 within a single pulse/ramp of the desired duration (determined from e.g. automated experiments to determine statistics for a given design of RRAM device 1, 8, 10). Some specific examples of suitable parameters for the preconditioning step 15 are explained in relation to FIG. 11 onwards.

Following the preconditioning step 15, during the filament forming step 16 the filament 14 is formed by passing a current I which exceeds the first current value I₁ through the RRAM device 1, 8, 10. For example, the filament forming step 16 may involve applying a voltage across the RRAM device 1, 8, 10 whilst limiting the current I through the RRAM device 1, 8, 10 to a second current value I₂ which is greater than the first current value I₂>I₁. Alternatively, the filament forming step 16 may involve driving a current of the second current value I₂ through the RRAM device 1, 8, 10. A voltage applied across the RRAM device 1, 8, 10 during the filament forming step may be less than or equal to the first voltage V₁. Often the voltage may be considerably lower than the first voltage V₁, and the precise level may be found by decreasing the voltage applied whilst maintaining the current at the second current value I₂. For example, using the circuit 11 of FIG. 4, the voltage applied between bit line BL and source line SL during the filament forming step may be as low as possible whilst keeping the transistor 12 saturated at the second current value I₂.

As shall be described in more detail hereinafter in relation to FIGS. 11 and 12, the multi-step electroforming method results in a significant and statistically resolvable drop in the maximum reset current Iᵣₑₛₑₜ for RRAM devices having notionally identical structures (see FIG. 11 in relation to an example of the first RRAM device 1 and FIG. 12 in relation to an example of the second RRAM device 8).

Without wishing to the be bound by theory, it is believed that the preconditioning step 15 serves to produce a controlled initial population of defects in the resistance switching layer 4, so that during the subsequent filament forming step 16 the electrical breakdown leading to the formation of the filament 14 happens within a range of voltages which is both lower than in the prior art, single step electroforming process and also more repeatable across a population of notionally identical RRAM devices 1, 8, 10.

Optionally, the method of electroforming may also include one or more development steps 17 (FIG. 7B) carried out between the preconditioning step 15 (FIG. 7B) and the filament forming step 16 (FIG. 7B). In other words, a sequence starts with the preconditioning step 15, ends with the filament forming step 16 and includes the one or more development steps 17. Each development step 17 includes passing a current I through the RRAM device 1, 8, 10 which exceeds a current limit applied during the preceding step of the sequence (i.e. the immediately prior development step 17 or the preconditioning step 15), in order that the development step 17 increases the conductance of the RRAM device 1, 8, 10 without forming the filament 14. The current passed through the RRAM device 1, 8, 10 during each development step 17 should also be less than the maximum current or current limit applied during a subsequent step of the sequence (i.e. the immediately following development step 17 or the filament forming step 16).

A development step 17 increases the conductance of the RRAM device 1, 8, 10 without forming the filament 14 if the conductance following that development step 17 is larger than the conductance before that development step 17. The comparison will be made as described in relation to the preconditioning step 15. Similarly to the preconditioning step, optimal values of the current levels for each current step may be calibrated from routine experiments, varying the number and magnitude of steps between the first current value I₁ and the second current value I₂. For example, each development step 17 may include applying a voltage across the RRAM device 1, 8, 10 (for example between the bit line BL and source line SL), whilst limiting the current through the resistive random access memory device to a corresponding current value which is greater than the first current value I₁ and less than the second current value I₂, and also lies between the current values of any preceding and/or following development steps 17.

Similarly to the filament forming step 16, the voltage applied during each development step 17 may be less than or equal to the first voltage V₁. In general, during each step of the sequence, the voltage applied may be less than or equal to the voltage during the preceding step. This may reduce voltage stress on other electronic components connected in series with the RRAM device 1, 8, 10. For example a series connected transistor (such as transistor 12 of circuit 11) used to limit the current I through the RRAM device 1, 8, 10.

In the general case, the sequence of the method may include any number N≥2 of steps, including at least the preconditioning step 15 and the filament forming step 16.

Referring also to FIG. 7A, a process-flow diagram is shown for the general case of the improved electroforming method, applied using a series transistor (for example transistor 12 of circuit 11) to apply current limits to each step 15, 16, 17.

The method is for electroforming a RRAM device 1, 8, 10 which includes a resistance switching material layer 4. The method starts with the first n=1 of N steps in the sequence (step S3). In other words, with the preconditioning step 15 FIG. 7B.

For each of the n^{th} of N steps forming the sequence, a pulse is applied across the RRAM device 1, 8, 10 and series connected current controlling transistor having a voltage Vₚᵤₗ=Vₙ, whilst the current I through the RRAM device 1, 8, 10 is limited to a maximum value Iₘₐₓ=Iₙ^{sat} by connecting the gate of the current controlling transistor to a corresponding bias voltage Vₙ^{G} (step S4) For example, using the circuit 11 shown in FIG. 4, the voltage Vₙ would be applied between the bit line BL and source line SL, whilst the gate of transistor 12 is connected to Vₙ^{G} via word line WL. In this way, the current controlling transistor (for example transistor 12 in circuit 11) is used as a constant current source. Accordingly, the method may instead be carried out using other type of constant current source, with the precise voltage over the actual RRAM device 1, 8, 10 being determined by the resistance of the RRAM device 1, 8, 10 and the controlled current Iₙ^{sat}. The durations of the pulses may be the same for all of the steps n, but do not need to be. For example, it may often be desirable that the duration of the preconditioning step 15 (n=1) is longer than that of subsequent development 17 and filament forming steps 16, to allow more time to develop an initial population of defects.

The following inequalities are satisfied by all implementations of the electroforming method:
N≥2, i.e. at minimum there is the preconditioning step 15 (n=1) and the filament forming step 16 (n=N).
V₁≥V_{TH1}, i.e. the voltage applied during the preconditioning step 15 (n=1) must always exceed the first threshold voltage V_{TH1} as defined hereinbefore.
I₁^{sat}<I_{N}^{sat}, i.e. the first current I₁=I₁^{sat} during the preconditioning step 15 (n=1) is always less than the second current I₂=I_{N}^{sat} during the filament forming step 16 (n=N).
Iₙ₋₁^{sat}<Iₙ^{sat}<Iₙ₊₁^{sat}∀1<n<N, i.e. for each development step 17 (n=2, . . . , N−1), the current Iₙ^{sat} is more than the previous step (n−1) and less than a subsequent step (n+1).

Moreover, each step (n<N) prior to the filament forming step 16 (n=N) must have the result of increasing conductance of the RRAM device 1, 8, 10, without forming the filament 14. The presence or absence of the filament 14 may be determined from the I-V characteristics of the RRAM device 1, 8, 10 as described hereinbefore.

In general, a first current value I₁=I₁^{sat} suitable for the pre-conditioning step 15 of any specific type (i.e. structure and materials) of RRAM device 1, 8, 10 may be determined by gradually increasing the current limit until a measurable increase in the conductance is observable. Similarly, the second current value I₂=I^{sat} may be determined from calibration experiments based on a desired median for the maximum reset current Iᵣₑₛₑₜ for the specific type of RRAM device 1, 8, 10. In other words, the second current value I₂=I_{N}^{sat} provides a parameter which can be used to tune (within physical limits) the size of the filament. The minimum second current value I₂=I_{N}^{sat} that is necessary to form a filament at all may vary in dependence on the preceding sequence (1, . . . , n, . . . , N−1) of the preconditioning step 15 and any development steps 17. The number (N−2) and spacing (in current values Iₙ^{sat}) of development steps 17 may be optimised by calibration experiments in a similar way, subject to the conditions explained hereinbefore. In practice, a number N of steps exceeding four or five is not expected to be routinely useful.

Optionally, the voltage Vₙ applied in each step 15, 16, 17 may also satisfy the condition Vₙ₋₁>Vₙ∀n>1, i.e. that the voltage applied across the RRAM device 1, 8, 10 and current controlling transistor (for example transistor 12 in circuit 11) is the same or lower for each step 16, 17 (n>1) after the preconditioning step 15 (n=1).

Referring again to FIG. 7A, unless the present step n is the filament forming step 16 (n=N) (step S5|No), the method progresses to the next step (n+1) in the sequence (step S6) and the next voltage pulse is applied (step S4).

If the filament forming step 16 (n=N) has been completed (step S5|Yes), then if there are further RRAM devices 1, 8, 10 to electroform (step S7|Yes), the method is repeated for each further RRAM device 1, 8, 10 in turn. For example, in the circuit 11, each RRAM device 1, 8, 10 in a 1T1R memory array may be electroformed by addressing the appropriate combination of bit line, BL, source line SL and word line WL.

Optionally though in some examples preferably, successful completion of at least some steps 15, 16, 17 of the sequence may be checked using a form-and-verify loop, and if necessary, the most recently applied step 15, 16, 17 may be repeated.

For example, after each voltage pulse (step S4), the state of the RRAM device 1, 8, 10 may be checked (step S8), with the sequence only progressing (step S5) if the effect of the current step n is verified (step S8|Yes). For the preconditioning step 15 (n=1) and each development step 17 (1<n<N), this test takes the form of confirming that the conductance of the RRAM device 1, 8, 10 has been increased (or equivalently that the resistance has decreased). For example, the test may be to determine that the conductance of the RRAM device 1, 8, 10 is greater than or equal to a conductance threshold for that step. For example, the conductance should exceed a preconditioning conductance threshold after the preconditioning step 15 (n=1). Similarly, each development step 17 (1<n<N) may have a corresponding development conductive threshold to ensure that the conductance has increased by a desired increment.

Such measurements may be conducted using a resistance measurement circuit which will also perform readout of the RRAM 1, 8, 10 value (1 or 0) in use. Alternatively, a dedicated resistance measurement circuit specific to electroforming may be used, which may be integrated with, or external to, a larger memory device including an array of RRAM devices 1, 8, 10).

For the filament forming step 16 (n=N), the test may simply correspond to verifying that the resistance of the RRAM device 1, 8, 10 is within an acceptable range for the LRS.

Additionally or alternatively, it may also be checked that the I-V characteristic is ohmic (linear), for example at least over the range+300 mV.

If the effect of the present step n is not confirmed (step S8|No), then provided a maximum number of pulses/attempts has not been reached (step S9|No), the present step n is repeated (step S4). If the maximum number of attempts is reached (step S9|Yes) without success, then the present RRAM device 1, 8, 10 may be flagged as failed/un-formable (step S10), and the method continues to the next RRAM device 1, 8, 10 (step S7) if any. The maximum number of attempts may be determined as required, although this is intended to mitigate for rare, unlucky failures due to the stochastic nature of the process, rather than for example manufacturing faults, so that increasing the number of allowed attempts beyond about two to four would have diminishing returns, and more than about ten would most likely be redundant.

Using a form-and-verify approach may help to improve a yield of electroformed (i.e. useable) RRAM devices 1, 8, 10. It may also improve the speed of electroforming, since the duration of pulse may be made shorter. The time taken before each step 15, 16, 17 occurs has a stochastic element. If a single pulse is used, the duration needs to be calibrated to ensure than almost all RRAM devices 1, 8, 10 will respond. Multiplied across millions of RRAM devices 1, 8, 10 in memory, accounting for the tail end of the temporal distribution in this can drastically reduce throughout. Using shorter pulses calibrated so that most RRAM devices 1, 8, 10 show the desired response after one or two pulses, may improve the overall speed of the electroforming process.

Form-and-verify loops (and repetition if needed) does not need to be performed after every step. In some examples, only the responses of the preconditioning step 15 (n=1) and the filament forming step 16 (n=N) may be checked. In other examples, only the filament forming step 16 (n=N) may be subject to a form-and-verify loop. In this latter example, in response to a failure to form the filament, the method may involve repeating only the filament forming step 16, or could involve restarting the electroforming process from the preconditioning step 15 (n=1).

Referring also to FIG. 7B, schematic signals illustrative of an electroforming method including one development step 17 are shown.

The example of FIG. 7B shall be explained with reference to the circuit 11 shown in FIG. 4, though other circuits using a transistor for current control could equally be used.

The example of FIG. 7B uses a sequence of three steps (N=3), including the preconditioning step 15 (n=1), one development step 17 (n=2), and the filament forming step 16 (n=N=3). In each step, the voltage pulse (step S4 in FIG. 7A) is applied between the bit line BL and source line SL as a top-hat function with amplitude V₁=V₂=V₃=Vₛ. During each step, the currents are limited to the desired values I₁^{sat}, I₂^{sat}, I₃^{sat} by biasing the gate of transistor 12 to corresponding gate voltages V₁^{G}, V₂^{G}, V₃^{G}.

The steps 15, 17, 16 have durations t₂-t₀, t₅-t₃ and t₈-t₆ respectively, and may be of equal duration (but do not need to be). The response of the RRAM device 1, 8, 10 during each step 15, 17, 16 occurs at times illustrated as t₁, t₄ and t₇ respectively. It should be remarked that these response times t₁, t₄, t₇ are not fixed, and have a stochastic element. When the response occurs, the current I through the RRAM device 1, 8, 10 increases rapidly to the current limit I₁^{sat}, I₂^{sat}, I₃^{sat} for the respective step 15, 17, 16, accompanied by a drop in the fraction V_{R}/V_{BS} of the applied voltage V₁, V₂, V₃ across the RRAM device 1, 8, 10.

The relative levels of voltages and currents shown in FIG. 7B, and the timings t₁, t₄, t₇ of the onset of RRAM device 1, 8, 10 responses, have been drawn for visual clarity and are not to scale.

In the example shown in FIG. 7B, each step n is separated from the preceding step n−1 and the following step n+1, the durations t₃-t₂ and t₆-t₅ as illustrated. In the general case, each step n of the sequence of N steps may start after a short delay following the end of the preceding step n-1. This may assist in reducing any transient effects from switching. For example, in the circuit 11, when the gate voltage of transistor 12 is switched from Vₙ^{G} to Vₙ₊₁^{G}, any transient ringing/overshoot could result in a corresponding pulse of current I above the desired limit Iₙ₊₁^{sat}. this can be avoided by staggering the switch in gate bias to occur during a delay/gap between steps, before the voltage pulse is applied between the bit line BL and source line SL. In other words, no current is passed through the RRAM device 1, 8, 10 during the delay.

Alternatively, if any such transient effects can be suppressed or can be tolerated, no delay between steps is needed, and each may flow continuously into the next. When delays are included, the delays between each pair of steps (n and n+1) may all have the same length, however this is not essential. In some examples, some steps may be separated by a delay, whilst others follow continuously, within the same sequence.

In some examples, a short pulse of current with the opposite polarity to the step currents Iₙ^{sat} may be passed through the RRAM device 1, 8, 10 during the delays between steps. This could be done by applying a voltage pulse or ramp of the opposite polarity of that used for the filament preconditioning 15, formation 16 or development 17 steps while limiting the current. When such reversals are used, preferably the current magnitude remains less than or equal to the magnitude of the first current value I₁=I₁^{sat} during any reversal. The reverse current may be applied after each step before the filament forming step 16, or only after some steps.

The precise values of currents Iₙ^{sat}, voltages Vₙ, pulse durations and delays will depend on the precise structure and materials used for the RRAM device 1, 8, 10. There will also be a dependence on the desired maximum reset current Iᵣₑₛₑₜ, though in practice this will most often be desired to be as low as possible to permit repeatable switching between the HRS and LRS of the RRAM device 1, 8, 10. Nonetheless, it is possible to specify ranges of these parameters which, without the intention to limit the appended claims, will be appropriate for most structures and material combinations suitable for forming an RRAM device 1, 8, 10:
A first current value I₁=I₁^{sat} between about 10 nA and 10 μA (preferably over 100 nA), and a duration of the preconditioning step between about 1 ns and 100 ms (preferably less than 500 μs);
A second current value I₂=I_{N}^{sat} between about 50 μA and 500 μA (preferably between 50 μA and 150 μA), and a duration between about 1 ns and 100 ms (preferably less than 500 μs);
Any development steps includes may have a duration between about 1 ns and 100 ms (preferably less than 500 μs), with currents controlled between the first I₁ and second I₂ currents are explained hereinbefore.
When delays between steps are included, these may range between about 10 ns and 1 ms.
The first voltage V₁ may be between about 3 V and 18 V (preferably between 3 V and 6V).

For example, in experimental examples of the first RRAM device 1 and the second RRAM device 8 and described in further detail in relation to FIGS. 11 to 15, three electroforming sequences were compared:
(i) A first current value I₁=I₁^{sat}=1 μA, a single development step 17 having current limit I₂^{sat}=10 μA, and a second current value I₂=I₃^{sat}=100 μA; (ii) A first current value I₁=I₁^{sat}=1 μA, no development steps 17, and a second current value I₂=I₂^{sat}=100 μA; and
(iii) A first current value I₁=I₁^{sat}=10 μA, no development steps 17, and a second current value I₂=I₂^{sat}=100 μA.

The electroforming method has been described as including a single voltage pulse (see step S4 in FIG. 7A) for each step 15, 16, 17. However, in general, two or more identical voltage pulses may be applied in each step 15, 16, 17. If a step if repeated due to, for example using form-and-verify methods (steps S8, S9, S10), then all of the two or more voltage pulses would be repeated.

### Mechanism

Without wishing to be bound by theory, the advantageous effects of the new electroforming method described herein may be illuminated by discussing the present understanding of the underlying mechanisms of filament 14 formation.

The preconditioning step 15 of the new electroforming method is believed to reduce the total energy involved in the creation of the filament 14. In the prior art, single-step electroforming process (illustrated in FIGS. 6A and 6B) with a current compliance determined by the desired maximal operational current (e.g. ~100 μA), the formation of the filament 14 involves both high voltages and currents. The creation of defects, for example oxygen vacancies when the resistance switching layer 4 is an oxide, is driven by the high electric field caused by the voltage applied RRAM device 1, 8, 10, and which is supported primarily across the resistance switching layer 4. For example, a voltage of 3 V across a 2.5 nm thick resistance switching layer results in a field of 12 MV·cm⁻¹. Such high fields cause some atomic bonds to break, generating defects in the atomic structure which facilitates an electron flow.

Until the point at which the filament 14 is formed, the conduction through the resistance switching layer 4 stack is non-filamentary, meaning that the electric field is relatively homogeneous over the entire active area, and thus the defect generation rate is similar throughout the metal-insulator-metal (MIM) area (assuming that no grain boundaries exists where the defect concentration might be higher even in the pristine insulator).

As the density of defects increases, a point is reached where local clusters are generated. Above a critical density of defects, a positive feedback loop is triggered: The cluster becomes conductive enough to allow an electrical current to flow through it, which in turn locally increases the temperature facilitating an ion hopping mechanism by which further oxygen vacancies can migrate towards the cluster. In this way, the cluster becomes enlarged until it connects between the electrodes 3, 5. In a pristine, highly insulating resistance switching material, for example an oxide, large electric fields are required to initiate this process, as the energy required to break the bonds between atoms and generate defects is high. Consequently, once the filament 14 forms, this high applied voltage results also in a high current, and the power dissipated in this scenario causes the filament 14 to grow in a rather uncontrolled way.

Moreover, the stochastic nature of the process means that the precise voltage across the resistance switching layer 4 when positive feedback starts is variable. This may be significant because there is a parasitic capacitance between the electrodes 3, 5, which stores energy which depends on the voltage. There are further parasitic capacitances associated with a current limiting/controlling transistor. These parasitic capacitors produce some transient currents when the filament 14 first forms, by bypassing the current limitation imposed by the series transistor. This can provide another source of variability in the energy driving filament formation. The initial preconditioning step 15, using a lower current limit I₁ than is used for a conventional single step electroforming, helps to decrease the total current during such current transients, because the current limitations enforced by the transistor starts to act faster.

The new electroforming methods described herein decouple the filament formation into at least two phases: By limiting the current through the RRAM device 1, 8, 10 during the preconditioning step, it is believed that the defect concentration and defects clusters are generated by the high field-driven defect generation mechanism previously mentioned. However, the limit to the first current value I₁ prevents the rapid increase of the current and associated abrupt (and poorly controlled) filament 14 expansion caused by massive temperature gradients produced in response to excessive power dissipation. The driving of the first current I₁ using a transistor at saturation (or comparable current source) results in a rapid decrease in the voltage across the resistance switching layer 4 as soon as the positive feedback loop previously described is triggered. This is also believed to reduce the probability of generating multiple conductive filaments in the same RRAM device, which is associated with poor performance as a memory.

In the subsequent filament forming step 16, the defect clusters created in the preconditioning step 15 serves as a preferable site for the nucleation of further defects vacancies, due to an increased temperature gradient in its vicinity (current preferentially flows via volumes of elevated defect concentration). Higher localized temperatures results in lower electric fields required to facilitate the ion hopping mechanism that will provide the developing filament with the required oxygen vacancies necessary to its growth. In this way, the total energy involved may be reduced. Moreover, the total energy dissipated in the process may be better controlled, potentially providing reduced variability in filament 14 diameters d_{f} and hence values of the LRS resistance between notionally identical RRAM devices 1, 8 10 in a memory.

Further control may be provided by the development steps 17. For example, by controlling intermediate points in the development between the pristine insulator and the clusters of defects at the point of positive feedback and filament 14 formation.

If a lower LRS resistance is needed (i.e. a larger filament d_{f}), further filament development steps (described further hereinafter) can be applied following the filament forming step 16, and allowing for controlled expansion of the filament. Such filament development steps will also happen at lower voltages (compared to a single step electroforming) due to increasing temperatures achieved in each step.

### Electroformed Devices

RRAM devices 1, 8, 10 are not generally produced or arranged for individual use. Instead, large arrays of RRAM devices 1, 8, 10 are configured to be individually addressable, for example using a 1T1R configuration such as the circuit 11 shown in FIG. 4. These arrays are combined with control circuitry (not shown) configured to provide the functions of writing RRAM devices 1, 8, 10 to the LRS or HRS (to encode bits), and reading out RRAM device 1, 8, 10 resistance states, to form a memory.

A memory based on RRAM devices 1, 8, 10 may be used for a variety of purposes, including but not limited to random access memory (RAM), as a read only module (ROM), to provide a register for a processor, or in larger arrays still for long term storage, in devices analogous to hard disc drives (HDDs), SD cards and so forth.

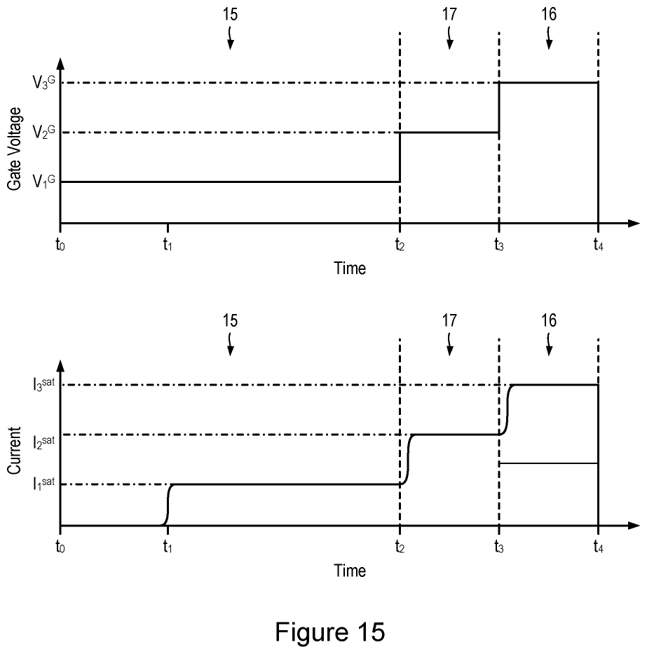

However, no memory based on RRAM devices 1, 8, 10 can be used until the constituent RRAM devices 1, 8, 10 have been electroformed. The nature of the electroforming process has an influence on the behaviour of the RRAM devices 1, 8, 10 for the operational lifetime of the memory. In particular, as shall be discussed further in relation to FIG. 15, the reduced maximum reset currents Iᵣₑₛₑₜ obtainable by electroforming RRAM devices 11 according to the multi-step methods described herein are stable against cycles of setting and resetting between the HRS and LRS.

Consequently, a memory electroformed using the new multi-step methods is distinguishable from a notionally identical memory electroformed using the prior art, single step electroforming process. Herein, a notionally identical, or comparative, memory has an identical pristine structure to the memory, i.e. the RRAM devices 1, 8, 10 have the same structure and materials.

A memory electroformed using the multi-step electroforming methods of the present specification will have a first distribution of maximum reset currents Iᵣₑₛₑₜ which has a first mean value I¹ₘₑₐₙ. A comparative memory electroformed using a single-step prior art electroforming method with have a second distribution of maximum reset currents Iᵣₑₛₑₜ which has a second mean value I²ₘₑₐₙ. The first mean value I¹ₘₑₐₙ will be lower than the second mean value I²ₘₑₐₙ (see for example FIGS. 11 and 12 hereinafter). Without wishing to be bound by theory, the difference is believed to be attributable to the improved control and reduced energy used to form the filament 14 in the multi-step method of the present specification.

To provide a meaningful comparison, in addition to having an identical pristine structure to the memory, the comparative memory cannot be regarded as having been “electroformed” unless the single current compliance step was such that a yield of electroformed RRAM devices 1, 8, 10 in the comparative memory is 95% or more. In other words, the prior art, single step electroforming does not correspond to an arbitrarily low target current I₀^{tar}—the target current I₀^{tar} must be at least large enough to provide a meaningful yield of RRAM device 1, 8, 10 that have a filament 14 formed.

A RRAM device 1, 8, 10 of the comparative memory may be considered to have been electroformed if:
It is capable of repeatable switching between the HRS and LRS;
In the LRS, there is a linear (Ohmic) relationship between current and voltage, at least over a range between (and including) −300 mV and 300 mV; and
There is a resistance contrast of at least two times. Resistance contrast may be the ratio of resistances between the HRS and LRS.

As an example, a specific prior art electroforming method usable to generate a comparative memory may take the form of applying a single ramped voltage pulse to a maximum of Vₘₐₓ=10 V, whilst limiting the current I through the RRAM device 1, 8, 10 to a target current I₀^{tar}≥50 μA.

When it is stated that the first mean value I¹ₘₑₐₙ will be lower than the second mean value I²ₘₑₐₙ, this refers to the mean values differing by an amount large enough to be statistically significant, with a significance level of 5% when using the appropriate statistical test. For example, the difference between the first mean I¹ₘₑₐₙ and the second mean I²ₘₑₐₙ may be greater than or equal to the larger of a first standard deviation of the first distribution and a second standard deviation of the second distribution. Referring to FIGS. 11 and 12, in the experimental examples the difference was found to be significantly larger still.

The use of the multi-step electroforming methods of the present specification to electroform a memory can also be determined from the absolute values of the maximum reset currents Iᵣₑₛₑₜ. For instance, the mean value I¹ₘₑₐₙ of the distribution of maximum reset currents Iᵣₑₛₑₜ will in most cases be less than or equal to 150 μA (but not all cases, for example a smaller LRS resistance may be desired, correspondingly increasing the maximum reset current Iᵣₑₛₑₜ.

### Reduction of Voltage Stresses

In the example shown in FIG. 7B, the voltages V₁, V₂, V₃ applied between the bit line BL and source line SL are all equal V₁=V₂=V₃=Vₛ. However, as described hereinbefore, in each step 16, 17 (n>1) after the preconditioning step 15, the voltage Vₙ may be less than or equal to the voltage Vₙ₋₁ during the previous step n−1.

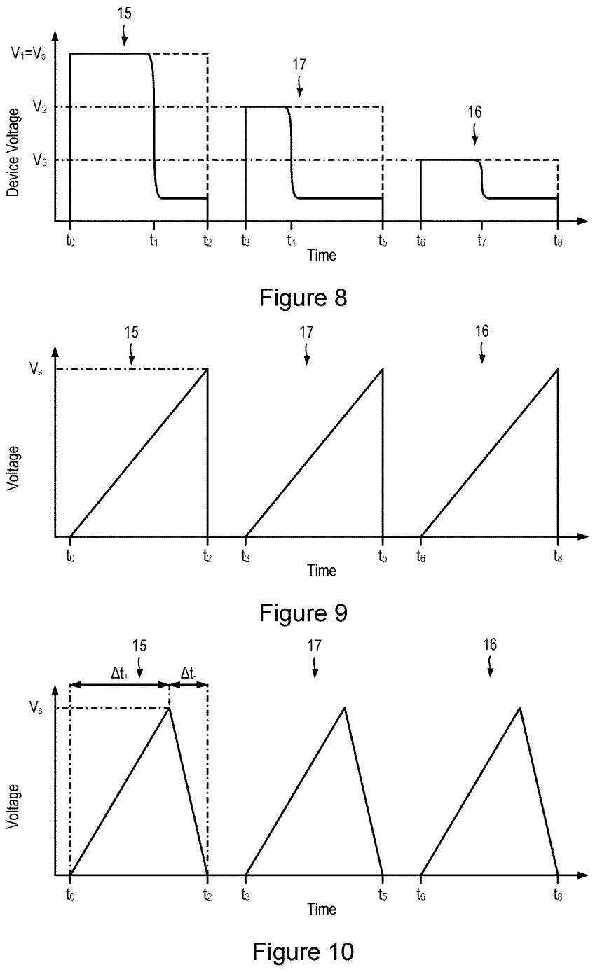

For example, as shown in the schematic voltage profiles shown in FIG. 8, in which V₁=Vₛ as for the FIG. 7B example, however V₂<V₁ and V₃<V₂. This approach may be advantageous in reducing the voltage stress applied to the current controlling transistor. In the 1T1R circuit 11 shown in FIG. 4, the transistor 12 is used both to control the currents Iₙ^{sat} during electroforming and also as the addressing transistor in use. Therefore, minimising the exposure of the transistor 12 to high voltage may help to prolong the operational lifetime of the 1T1R cell (i.e. circuit 11).

### Waveform of Voltage Pulses

The multi-step electroforming methods of the present specification have been explained in relation to voltage pulses (step S4 in FIG. 7A) which take the form of a top-hat function. In other words, each first voltage pulse has the form of a single half-cycle of a square wave.

However, this is not essential, and other waveforms may be used to provide the voltage pulses (step S4 in FIG. 7A), subject to the amplitude being equal to the voltage value Vₙ for that pulse, and the current being limited to Iₙ^{sat}.

Referring also to FIG. 9, a second example of voltage pulses for multi-step electroforming is schematically shown.

In the second example shown in FIG. 9, each voltage pulse has a waveform in the form of a linear voltage ramp. Although in FIG. 9, the maximum voltage of each illustrated pulse is the same (V₁=V₂=V₃=Vₛ), this is not essential, and each voltage pulse may be scaled to an amplitude Vₙ, wherein Vₙ₋₁≥Vₙ as explained hereinbefore.

Although FIG. 9 illustrates a linear ramp, a ramped voltage pulse may be non-linear, for example logarithmic, stepped and so forth.

Referring also to FIG. 10, a third example of voltage pulses for multi-step electroforming is schematically shown.

In the third example shown in FIG. 10, each voltage pulse has a waveform in the form of a triangular waveform. The triangular waveforms shown in FIG. 10 are asymmetric (in time) about the maximum voltage value, with a rising time to peak Δt+ being larger than a falling time Δt− after the peak. However, symmetric triangular waveforms could be used such that Δt+=Δt−.

Although in FIG. 10, the peak voltage of each illustrated pulse is the same (V₁=V₂=V₃=Vₛ), this is not essential, and each voltage pulse may be scaled to an amplitude Vₙ, wherein Vₙ₋₁≥Vₙ as explained hereinbefore

### Experimental Comparisons

Referring also to FIG. 11, measured distributions of maximum reset currents Iᵣₑₛₑₜ are shown for experimental examples of the first RRAM device 1 (see also FIG. 1).

The experimental examples of the first RRAM device 1 had a 3 nm thick silicon oxide SiOₓ resistance switching layer 4 and a 4 nm thick tantalum Ta metal scavenging layer 2.

Three patterns of current values Iₙ^{sat} were used for multi-step electroforming:
(i) A first current value I₁=I₁^{sat}=1 μA, a single development step 17 having current limit I₂^{sat}=10 μA, and a second current value I₂=Iₛ^{sat}=100 μA;
(ii) A first current value I₁=I₁^{sat}=1 μA, no development steps 17, and a second current value I₂=I₂^{sat}=100 μA; and
(iii) A first current value I₁=I₁^{sat}=10 μA, no development steps 17, and a second current value I₂=I₂^{sat}=100 μA.

For comparison, a single step electroforming according to the prior art method was also conducted:
(iv) A single step with target current I₀^{tar}=100 μA.

FIG. 11 presents box and whisker plots for measurements of maximum reset currents Iᵣₑₛₑₜ obtained from experimental examples of the first RRAM device 1 electroformed used each of the four electroforming process (i), (ii), (iii) and (iv). Thirty four experimental first RRAM devices 1 were measured for each electroforming process.

For the experimental results, all the electroforming methods used voltage ramps (triangular voltage signals) with a ramp rate of around 20 mV/sec, and with a decreasing max. voltage Vₙ for each subsequent voltage ramp: V₁=Vₘₐₓ=4.5 V, V₂=3.0 V and V₃=2.5 V. If an electroforming method did not use a step, the corresponding Vₙ value was not used for that method.

Following electroforming, the experimental examples of the first RRAM device 1 were reset with a voltage ramp of the opposite polarity (i.e. negative voltage) to −1.2 V, and the maximum reset currents Iᵣₑₛₑₜ were defined as the highest currents I registered during this reset sweep.

Referring also to FIG. 12, measured distributions of maximum reset currents Iᵣₑₛₑₜ are shown for experimental examples of the second RRAM device 8 (see also FIG. 2). Thirty four experimental second RRAM devices 8 were measured for each electroforming process.

The experimental examples of the first RRAM device 1 had a 3 nm thick silicon oxide SiOₓ resistance switching layer 4 and a 30 nm thick tantalum oxide TaOₓ conductive oxide layer 9. The electroforming processes and method of determining maximum reset currents Iᵣₑₛₑₜ was the same as for the data shown in FIG. 11.

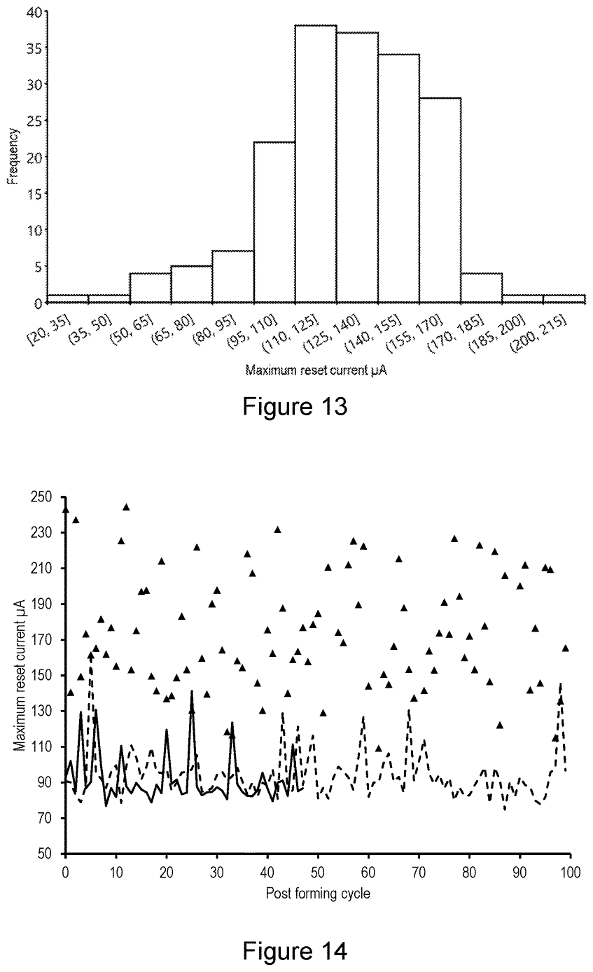

Referring also to FIG. 13, a histogram is shown presenting the same data as the box and whisker plot corresponding to process (i) in FIG. 11.

Referring also to FIG. 14, data is shown for post-electroforming cycling of setting and resetting an RRAM device.

After the initial reset, RRAM devices were cycled through setting and resetting multiple times. The maximum reset current Iᵣₑₛₑₜ was read-off from the I-V characteristics for each switching cycle, and the data is plotted in FIG. 14. The structures and materials of RRAM devices were the same as for the data shown in FIGS. 11 to 13. Switching cycles were conducted using ramped voltage sweeps up to 2.5 V to set and then down to −1.2 V to reset.

The solid line series corresponds to an experimental example of the second RRAM device 8 electroformed using process (i), and cycling data is plotted for 47 switching cycles. The dashed line series corresponds to an experimental example of the first RRAM device 1 electroformed using process (i), and cycling data is plotted for 99 switching cycles. The series plotted with filled triangular markers corresponds to an experimental example of the second RRAM device 8 electroformed using the prior art process (iv), and cycling data is shown for 99 switching cycles.

It should be noted that five of the data-points for the prior art process (iv) were unusable and are omitted from FIG. 14, because analysis of the I-V characteristics showed that the switching between HRS and LRS had failed. Switching failures were not observed for the process (i) data.

From the experimental data presented in FIGS. 11 to 14, several points may be observed. Firstly, for both metal scavenging layers 2 (in FIG. 11) and conductive oxide layers 9 (in FIG. 12), the distributions of maximum reset currents Iᵣₑₛₑₜ are significantly lower for the multi-step electroforming processes (i), (ii), (iii) when compared to the prior art process (iv). It may also be observed that using the prior art electroforming process, the average reset currents Iᵣₑₛₑₜ are a factor of approximately three times the current compliance used I₀^{tar}=100 μA.

FIGS. 11 and 12 provide an example of the comparison with a comparative electroformed RRAM device discussed hereinbefore, and demonstrate that it is possible to clearly distinguish a memory electroformed using the multi-step methods of the present specification from a memory having identical pristine structure but electroformed using the prior art method. Whilst these differences in measured electrical parameters of resistance switching reflect underlying physically differences in the filaments 14. However, these would likely require a combination of ion-beam milling and transmission electron microscopy to be imaged, so that parameterisation based on maximum reset currents Iᵣₑₛₑₜ is more practical as a measure of the differentiation resulting from how devices have been electroformed.

Referring in particular to FIG. 14, it may also be observed that the reset currents Iᵣₑₛₑₜ observed immediately after electroforming are stable to subsequent cycles. Both series corresponding to the three-step process (i) show a similar pattern, namely variation around ~90 μA, with sporadic spikes to higher reset currents between ~130 μA to 150 μA which are believed to result from the natural variability in the precise set voltage Vₛₑₜ during each switching cycle. Importantly, no upward trend is observed for either type of RRAM device 1, 8.

The series corresponding to the prior art electroforming process (iv) may be observed to exhibit a greater variance between switching cycles, including as mentioned hereinbefore some failed switching cycles. However, no downward trend is observed.

Overall, the cycling data suggests that the switching behaviour is determined by the initial electroforming, and there is no indication that the behaviours would approach a common equilibrium as more and more switching cycles are conducted.

A second observation may be made about the effect of the electroforming process used on the variability between switching cycles of the resulting RRAM devices 1, 8. Referring in particular to FIG. 11, for RRAM devices 1 using metal scavenging layers 2 no trend is immediately evident in the overall distribution widths. However, referring in particular to FIG. 12, in the RRAM devices 8 using the conductive oxide layers 9, there is a clear and significant reduction in the distribution of reset currents Iᵣₑₛₑₜ, which reflects an improved consistency of behaviour between switching cycles.

### Second Multi-Step Electroforming Method

The multi-step electroforming process has been described in relation to FIG. 7A as being applied using one or more voltage pulses per step. However, other approaches may equally be used to provide the appropriate control over the currents Iₙ^{sat} for each step n.

In a second example, the filament forming step 16 is not defined by a separate voltage pulse, but rather by ramping up the current I passing through the RRAM device 1, 8, 10. When one or more development steps 17 are used, each may be similarly defined by a ramping up of the current I.

In other words, the boundary between steps n and n+1 may be defined by ramping up the maximum current from Iₙ^{sat} to Iₙ₊₁^{sat}, rather than as separate pulses. Throughout the sequence, a constant potential Vₛ may be applied across the RRAM device 1, 8, 10 and a current controlling transistor (for example between bit line BL and source line SL in the circuit 11 of FIG. 4).

Referring also to FIG. 15, schematic electrical parameters of an example of the second method including a single development step 17 are shown.

The example shown in FIG. 15 is applied using the circuit 11 shown in FIG. 4, with a constant voltage Vₛ applied between the bit line BL and source line SL throughout. During the preconditioning step 15 (n=1) between times to and t₂, the current is limited to the first current I₁=I₁^{sat} by connecting the gate of transistor 12 to a bias of V₁^{G} via word line WL. No significant current flows immediately. As described hereinbefore the response of the RRAM device 1, 8, 10 occurs at a time t₁ which will vary slightly for each RRAM device 1, 8, 10. At this point the current rises rapidly, before being truncated at I₁^{sat}.

The development step 17 starts at time t₂ and is implemented by stepping up the transistor 12 gate bias to V₂^{G}. Shortly afterwards the current I ramps up to the new limit I₂^{sat} (again, the precise timing can vary). Similarly, the filament forming step 16 starts at time t₃ and is implemented by stepping up the transistor 12 gate bias to V₃^{G}, corresponding to the second current I₂=I₃^{sat}. The precise timing of the current step can vary slightly between RRAM devices 1, 8, 10. The electroforming process ends at time t₄. Generally, the preconditioning step 15 will be the longest, because the initial response shows the greatest variability. In subsequent steps 17, 16, the increase in current limit corresponds to removing an interruption to the positive feedback process of forming the filament 14, and the response is generally observed within a shorter and less variable time period.

The example shown in FIG. 15 uses step-function ramps in the current limit. However, any other suitable ramping function may be used to transition between steps n→n+1 of the sequence including, without being limited to, a staircase function, a linear function or a non-linear function such as a sigmoid function, a logarithmic function, and so forth. Ramping functions may be continuous or discontinuous, and may be the same between each pair of steps, or different between some steps. For example, a different current ramping function may be used for the final transition to the filament forming step 17.

### Third Method

A still further alternative method for improving the control of electroforming is to consider the limit as the number of development steps becomes essentially continuous.

In this third method, a constant voltage Vₛ or ramped voltage Vₛ(t) is applied whilst limiting the current I through the RRAM device 1, 8, 10 to a time-varying current value I^{sat}(t) which increases with time. For example, using the circuit 11, the gate bias of transistor 12 may be a function of time V^{G}(t) which gradually increases to correspondingly increase the saturation current I^{sat}(V^{G}).

The actual current I will not follow the current limit value I^{sat}(t) until the breakdown process initiates—see for example the transitions at times t₁ in FIGS. 7B and 15. The precise timing of this onset is stochastic. Therefore, it is important to ensure that the rate of increase of I^{sat}(t) is calibrated so that the limit I^{sat}(t) remains at or below the first current I₁ within the most likely time window for the onset.

The electrical breakdown of the resistance switching layer 4 may be modelled based on a probability of breakdown per unit time which is a function of the applied electric field |E|, and hence for RRAM devices 1, 8, 10 with fixed thickness a function of voltage P_{bd}(V). The probability of surviving a time period δt without onset of breakdown may be considered to be δt(1−P_{bd}(V)), and this probability may be considered roughly independent for each successive time period δt. Consequently, the probability of survival over time is a geometric series, and the cumulative probability distribution for the onset of breakdown typically has a sigmoid shape. One example of a statistical model suitable for modelling the cumulative probability distribution for the onset of breakdown is a Weibull distribution.

The probability of breakdown P_{bd}(V) is typically only definable above a minimum threshold, below which the atomic-scale processes involved in breakdown (e.g. defect formation) are effectively frozen out. Above this, the nature of the failure probability statistics are such that increases in P_{bd}(V) lead to rapidly shortening times until the average onset of breakdown. Thus, a single breakdown voltage for a given pristine RRAM device 1, 8, 10 will depend on the time history of the applied voltage—applying a higher constant voltage will tend to shift the breakdown time earlier.

For the sake of definiteness in the third method of electroforming, the cumulative probability distribution for breakdown of the specific RRAM devices 1, 8, 10 should be measured in calibration experiments using the same applied voltage profile (e.g. ramped or constant) as is intended to be used for the electroforming. The rate of increase of the time-varying current limit value I^{sat}(t) is controlled so that I^{sat}(t) does not exceed the first current value I₁ before the cumulative probability of breakdown exceeds 0.95.

In this way, the period when Iₛₐₜ(t)≤I₁ corresponds to the preconditioning step 15. The subsequent period when Iₛₐₜ(t)>I₁ corresponds to the filament forming step 16 (an alternative view is that there is a continuum of development steps 17 whilst I₂<Iₛₐₜ(t)≤I₂).

The cumulative probability of breakdown for a given resistive random access memory device and a given constant Vₛ or ramped Vₛ(t) voltage profile may be readily measured.

For example, the same Vₛ or ramped Vₛ(t) voltage profile intended for use to electroform RRAM devices 1, 8, 10 may be applied to a large number of the RRAM devices 1, 8, 10 (for example several hundred) whilst the current I is not limited or limited to a relatively high value such as I₀^{tar}=100 μA or more. In other words, the prior art, single step electroforming process is carried out.

The time to breakdown may be determined by monitoring the current I through each RRAM device 1, 8, 10, with breakdown corresponding to a transition from low (leakage) current to a higher current as a filament 14 is formed (when the current I is not limited or not sufficiently limited to prevent filament formation). In this way, the cumulative probability of breakdown as a function of time may be determined. The time to a cumulative breakdown probability of 0.95 may be calculated by interpolation. Alternatively, a Weibull distribution (or other distribution having comparable shape) may be fitted to the time-to-breakdown data, and then used to estimate the time corresponding to a cumulative breakdown probability of 0.95. Following such measurements, the rate of increase of the current limit value I^{sat}(t) may be calibrated as defined hereinbefore, and then applied for electroforming.

The rate of increase of the time-varying current limited value I^{sat}(t) may be linear or non-linear, though a non-linear function may be preferable to ensure the preceding conditions are met for the preconditioning step 15 without unduly extending the duration needed for the filament forming step 17.

### Fourth Method

An alternative to calibrating the duration of the preconditioning step 15 is to simply monitor the current I through an RRAM device 1, 8, 10 to detect the onset of breakdown via the increase in current I (equivalently, an increase in conductance), and to then trigger the filament forming step 16 immediately or after a short delay.

In this way, in response to detecting success of the preconditioning step 15, the current limit I₁=Iₙ^{sat} is increased to generate the filament 14 in a controlled manner. This approach may be used for sequences including development steps 17 (N≥2), for example by triggering the n+1th step in response to detecting the response of the RRAM device 1, 8, 10 to the preceding n^{th} step.

As described hereinbefore, a delay may optionally be inserted between detecting success of the n^{th} step and starting the n+1^{th} step. During such delay, a voltage Vₙ applied across the RRAM device 1, 8, 10 may be reduced or removed. Alternatively, during the delay between detecting success of the n^{th} step and starting the n+1th step, the applied voltage Vₙ and current limit Iₙ^{sat} of the n^{th} step may be maintained.

### Modifications

It will be appreciated that various modifications may be made to the embodiments hereinbefore described. Such modifications may involve equivalent and other features which are already known in the design, configuration, manufacture and/or use of resistive random access memory device and memories formed thereof, and which may be used instead of or in addition to features already described herein. Features of one embodiment may be replaced or supplemented by features of another embodiment.

In some cases, it may be undesirable to develop the filament 14 to the desired size in a single step. For example, when a lower resistance of the LRS is intended. Forming a large filament 14 (corresponding to reduced LRS resistance) in a single step can partly re-introduce the issue of uncontrolled energy dissipation during the filament formation 14.

An approach to mitigate this is to form a small filament 14 in the filament forming step 16, for example by finding the smallest second current I₂ necessary to obtain the Ohmic I-V behaviour indicating that the filament 14 is formed. The size of the filament 14 may then be increased by extending the electroforming method to include one or more filament development steps (not shown) carried out after the filament 14 forming step 16. In each successive filament development step, the current limit may be increased, allowing for progressive and controlled development of the filament 14. Increases in the filament 14 size will register as increased conductance of the RRAM device 1, 8, 10.

In general a number M≥1 of filament development steps may be used, with the current limit during the m^{th} of M filament development steps obeying the conditions I₂<I_{N+m}^{sat} and I_{N+m}^{sat}<I_{N+m+1}^{sat}.

In the preceding description, the multi-step electroforming methods have been described in the context of controlling the current values Iₙ^{sat} for each step using a field-effect transistor operated in saturation mode and connected in series with the RRAM device 1, 8, 10. In effect, providing a constant current source.

However, the methods described herein may be applied to electroforming of RRAM devices 1, 8, 10 using other types of constant current source, including bipolar junction transistor circuits, or other types of constant current sources having greater complexity than a single transistor (for example including multiple transistors and further components).

For example, a single, adjustable constant current source (not shown) may be connected in series with a RRAM device 1, 8, 10 to apply the electroforming method. Alternatively, two or more constant current sources (not shown) having different output currents may be connectable in series with a RRAM device 1, 8, 10 in a multiplexed arrangement.

Although described with reference to the first, second and third RRAM devices 1, 8, 10 (see FIGS. 1, 2 and 3), a scavenging metal layer 2 and/or conductive oxide layer 9 is not essential for the present electroforming methods, though these features are associated with other desirable properties which is why they are typically included.

Nonetheless, the multi-step electroforming methods of the present specification should be applicable to provide increased control and reduced maximum reset currents Iᵣₑₛₑₜ to any type of RRAM device having a resistance switching layer 4 arranged between a pair of electrodes.

Further examples of suitable combinations of materials for RRAM devices to electroform using the methods described herein are outlined in the “Summary” section hereinbefore.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A method comprising:
electroforming a resistive random access memory device which comprises a resistance switching material, the electroforming comprising:
a preconditioning step in which a first voltage exceeding a first threshold voltage is applied across the resistive random access memory device whilst limiting a current through the resistive random access memory device to a first current value, wherein the preconditioning step increases the conductance of the resistive random access memory device without forming a filament;
a filament forming step after the preconditioning step, in which the filament is formed by passing a current which exceeds the first current value through the resistive random access memory device.

2. The method of claim 1, wherein the electroforming further comprises one or more development steps carried out between the preconditioning step and the filament forming step;
wherein a sequence starts with the preconditioning step, ends with the filament forming step and includes the one or more development steps, and wherein each given development step of the one or more development steps comprises:
passing a current through the resistive random access memory device which exceeds a current limit applied during the preceding step of the sequence, such that the given development step increases the conductance of the resistive random access memory device without forming the filament.

3. The method of claim 1, wherein the filament forming step comprises ramping up the current passing through the resistive random access memory device.

4. The method of claim 1, wherein each step starts immediately following the preceding step.

5. The method of claim 1, wherein a delay separates the start of each step from the end of the preceding step.

6. The method of claim 1, wherein the filament forming step comprises applying a voltage across the resistive random access memory device whilst limiting the current through the resistive random access memory device to a second current value which is greater than the first current value.

7. The method of claim 6, wherein the electroforming further comprises one or more development steps carried out between the preconditioning step and the filament forming step;
wherein a sequence starts with the preconditioning step, ends with the filament forming step and includes the one or more development steps, and wherein each given development step of the one or more development steps comprises:
passing a current through the resistive random access memory device which exceeds a current limit applied during the preceding step of the sequence, such that the given development step increases the conductance of the resistive random access memory device without forming the filament; and
wherein each given development step of the one or more development steps comprises applying a voltage across the resistive random access memory device whilst limiting the current through the resistive random access memory device to a corresponding current value which is greater than the first current value and less than the second current value.

8. The method of claim 1, wherein the first current value is between 10 nA and 10 μA.

9. The method of claim 1, wherein a maximum current during the filament forming step is greater than or equal to 50 μA and less than or equal to 500 μA.

10. The method of claim 2, wherein a current limit during each given development step of the one or more development steps is greater than or equal to 1 μA and less than or equal to 100 μA.

11. The method of claim 1, wherein the electroforming further comprises one or more filament development steps carried out after the filament forming step;
wherein a second sequence starts with the filament forming step and progresses through the one or more filament development steps, and wherein each given filament development step of the one or more filament development steps comprises:
passing a current through the resistive random access memory device which exceeds a current limit applied during the preceding step of the second sequence, such that the given filament development step increases the conductance of the filament.

12. The method of claim 1, wherein a maximum voltage applied across the resistive random access memory device during the preconditioning step is less than or equal to 6 V.

13. The method of claim 1, wherein a maximum voltage applied across the resistive random access memory device during the preconditioning step is less than or equal to 18 V.

14. The method of claim 1, wherein currents are passed through the resistive random access memory device using one or more constant current sources.

15. The method of claim 14, wherein at least one constant current source of the one or more constant current sources comprises a transistor connected or connectable in series with the resistive random access memory device.

16. The method of claim 1, applied to a resistive random access memory device comprising:
a first electrode;
a second electrode; and
a resistance switching layer between the first electrode and the second electrode, the resistance switching layer formed from a first oxide.

17. The method of claim 16, wherein the resistance switching layer is formed from one or more of silicon oxide, silicon dioxide, silicon nitride, silicon carbide and silicon oxynitride.

18. The method of claim 1, wherein:
the preconditioning step comprises applying one or more first voltage pulses across the resistive random access memory device whilst limiting the current through the resistive random access memory device to the first current value; and
the filament forming step comprises applying one or more second voltage pulses across the resistive random access memory device whilst limiting the current through the resistive random access memory device to a second current value which is greater than the first current value.

19. The method of claim 18, wherein each first voltage pulse takes the form of a top-hat function.

20. The method of claim 18, wherein the preconditioning step comprises:
a) applying a first voltage pulse;
b) measuring the conductance of the resistive random access memory device;
c) in response to the conductance is less than a preconditioning conductance threshold, returning to step a); and
d) in response to the resistance is greater than or equal to the preconditioning conductance threshold, finishing the preconditioning step.

21. The method of claim 1, comprising:
applying a constant or ramped voltage across the resistive random access memory device whilst limiting the current through the resistive random access memory device to a time-varying current value which increases with time;
wherein a rate of increase of the time-varying current value is controlled such that the time-varying current value does not exceed the first current value before the cumulative probability of breakdown for the resistive random access memory device exceeds 0.95.

22. The method of claim 1, wherein the preconditioning step comprises monitoring the current through the resistive random access memory device;
wherein the method progresses from the preconditioning step to the filament forming step, or the first development step when dependent from claim 2, in response to detecting an increase in the conductance through the resistive random access memory device exceeding a preconditioning conductance threshold.

23. A memory comprising a plurality of resistive random access memory devices, each resistive random access memory device electroformed by:
application of preconditioning step in which a first voltage exceeding a first threshold voltage is applied across the resistive random access memory device whilst limiting a current through the resistive random access memory device to a first current value, wherein the preconditioning step increases the conductance of the resistive random access memory device without forming a filament;
application of a filament forming step after the preconditioning step, in which the filament is formed by passing a current which exceeds the first current value through the resistive random access memory device.

24. A memory comprising a plurality of resistive random access memory devices, each resistive random access memory device comprising a resistance switching layer formed from a material which exhibits resistance switching;
wherein a mean of a distribution of maximum reset currents from switching the plurality of resistive random access memory devices is less than or equal to 150 μA.

25. A memory comprising a plurality of resistive random access memory devices, wherein a first mean of a first distribution of maximum reset currents from switching the plurality of resistive random access memory devices is less than a second mean of a second distribution of maximum reset currents from switching a second plurality of resistive random access memory devices comprised by a comparative memory;
wherein the comparative memory has an identical pristine structure to the memory, and the second plurality of resistive random access memory devices of the comparative memory are each electroformed using a single current compliance step such that a yield of electroformed resistive random access memory devices is 95% or more.
